(19) United States
(12) Patent Application Publication
(10) Pub. No.: US 2021/0139690 A1
(43) Pub. Date: May 13, 2021

(54) LIGHT-SHIELDING COMPOSITION, CURED FILM, COLOR FILTER, LIGHT-SHIELDING FILM, OPTICAL ELEMENT, SOLID-STATE IMAGING ELEMENT, AND HEADLIGHT UNIT

(71) Applicant: FUJIFILM Corporation, Tokyo (JP)

(72) Inventor: Takahiro Oya, Haibara-gun (JP)

(73) Assignee: FUJIFILM Corporation, Tokyo (JP)

(21) Appl. No.: 17/155,891

(22) Filed: Jan. 22, 2021

Related U.S. Application Data
(63) Continuation of application No. PCT/JP2019/032367, filed on Aug. 20, 2019.

(30) Foreign Application Priority Data
Sep. 20, 2018 (JP) 2018-176215

(51) Int. Cl. C08L 35/02; F21S 41/43; G02B 5/00; H01L 27/146

(52) U.S. Cl. CPC C08L 35/02; F21S 41/43; C08L 2205/025; H01L 27/14623; G02B 5/003

(57) ABSTRACT

A light-shielding composition contains a black coloring material, a resin, a polymerizable compound, a polymerization initiator, and particles, in which the particle diameter of each of the particles is equal to or greater than 1 nm and less than 100 nm, and a mass ratio of a content of the particles to a content of the black coloring material is 0.01 to 0.25.

### CROSS-REFERENCE TO RELATED APPLICATIONS

This application is a Continuation of PCT International Application No. PCT/JP2019/032367 filed on Aug. 20, 2019, which claims priority under 35 U.S.C § 119(a) to Japanese Patent Application No. 2018-176215 filed on Sep. 20, 2018. Each of the above application(s) is hereby expressly incorporated by reference, in its entirety, into the present application.

### BACKGROUND OF THE INVENTION

### 1. Field of the Invention

The present invention relates to a light-shielding composition, a cured film, a color filter, a light-shielding film, an optical element, a solid-state imaging element, and headlight unit.

### 2. Description of the Related Art

A color filter used in a liquid crystal display device comprises a light-shielding film which is called a black matrix, for the purpose of shielding light between colored pixels, enhancing contrast, and the like.

Furthermore, currently, a compact and thin imaging unit is mounted on a mobile terminal of electronic equipment such as a mobile phone and a personal digital assistant (PDA). A solid-state imaging element such as a charge coupled device (CCD) image sensor and a complementary metal-oxide semiconductor (CMOS) image sensor is provided with a light-shielding film for the purpose of preventing the generation of noise, improving image quality, and the like.

As a composition for forming a light-shielding film for a solid-state imaging element, a light-shielding composition containing a black coloring material such as carbon black and titanium black is known. For example, JP2011-048195A discloses a photosensitive composition for forming a partition wall of an optical element, the composition including: an alkali-soluble resin having a photocurable ethylenically unsaturated double bond; a photopolymerization initiator; a black pigment; and hollow particles having a specific average primary particle diameter.

### SUMMARY OF THE INVENTION

As a result of conducting an investigation on a cured film formed of the photosensitive composition for forming a partition wall described in JP2011-048195A, the present inventors have found that there is a possibility that low-reflection properties, in-plane uniformity of a reflectivity, and light-shielding properties, which have been increasingly required in recent years, cannot be sufficiently satisfied.

Accordingly, an object of the present invention is to provide a light-shielding composition from which a light-shielding film having excellent low-reflection properties, in-plane uniformity of a reflectivity, and light-shielding properties can be formed. Moreover, another object of the present invention is to provide a cured film, a color filter, a light-shielding film, an optical element, a solid-state imaging element, and a headlight unit.

As a result of conducting an extensive investigation, the present inventors have found that the objects can be achieved by the following constitution, and have completed the present invention.

[1]

A light-shielding composition comprising: a black coloring material; a resin; a polymerizable compound; a polymerization initiator; and particles, in which a particle diameter of each of the particles is equal to or greater than 1 nm and less than 100 nm, and a mass ratio of a content of the particles to a content of the black coloring material is 0.01 to 0.25.

[2]

The light-shielding composition as described in [1], in which the content of the black coloring material is greater than 50% by mass and equal to or less than 90% by mass with respect to a total solid content of the light-shielding composition.

[3]

The light-shielding composition as described in [1] or [2], in which the particles contain an inorganic oxide, an inorganic nitride, a carbonate, or a resin.

[4]

The light-shielding composition as described in any one of [1] to [3], in which the particles contain an inorganic oxide.

[5]

The light-shielding composition as described in any one of [1] to [4], in which the particles contain at least one selected from the group consisting of silica, titania, and alumina.

[6]

The light-shielding composition as described in any one of [1] to [5], in which the particles are particles having a hollow structure.

[7]

The light-shielding composition as described in any one of [1] to [6], in which the content of the particles is greater than 1% by mass and less than 10% by mass with respect to a total solid content of the light-shielding composition.

[8]

The light-shielding composition as described in any one of [1] to [7], in which the black coloring material is an inorganic pigment.

[9]

The light-shielding composition as described in any one of [1] to [8], in which the black coloring material contains an oxynitride of at least one metal selected from the group consisting of titanium, vanadium, zirconium, and niobium.

[10]

The light-shielding composition as described in any one of [1] to [9], in which the polymerization initiator is an oxime compound.

[11]

The light-shielding composition as described in any one of [1] to [10], in which the polymerization initiator is a compound represented by Formula (C-3).

[12]

A cured film formed of the light-shielding composition as described in any one of [1] to [11].

[13]

A color filter comprising the cured film as described in [12].

[14]

A light-shielding film comprising the cured film as described in [12].

[15]

An optical element comprising the cured film as described in [12].

[16]

A solid-state imaging element comprising the cured film as described in [12].

[17]

A headlight unit for a vehicle lighting tool, the headlight unit comprising: a light source; and a light-shielding part which shields at least a part of light emitted from the light source, in which the light-shielding part includes the cured film as described in [12].

According to the present invention, an object is to provide a light-shielding composition from which a light-shielding film having excellent low-reflection properties, in-plane uniformity of a reflectivity, and light-shielding properties can be formed. Moreover, according to the present invention, it is possible to provide a cured film, a color filter, a light-shielding film, an optical element, a solid-state imaging element, and a headlight unit.

### BRIEF DESCRIPTION OF THE DRAWINGS

FIG. 1 is a schematic cross-sectional view showing an example of the constitution of a solid-state imaging device.

FIG. 2 is a schematic cross-sectional view showing an imaging part comprised in the solid-state imaging device shown in FIG. 1 in an enlarged manner.

FIG. 3 is a schematic cross-sectional view showing an example of the constitution of an infrared sensor.

FIG. 4 is a schematic view showing an example of the constitution of a headlight unit.

FIG. 5 is a schematic perspective view showing an example of the constitution of a light-shielding part of the headlight unit.

FIG. 6 is a schematic view showing an example of a light distribution pattern formed by the headlight unit.

FIG. 7 is a schematic view showing another example of the light distribution pattern formed by the headlight unit.

### DESCRIPTION OF THE PREFERRED EMBODIMENTS

Hereinafter, the present invention will be described in detail.

The description of the following constituting requirements is made based on typical embodiments of the present invention in some cases, but the present invention is not limited to the embodiments.

Furthermore, in the present specification, a numerical range expressed using “to” means a range including numerical values described before and after “to” as a lower limit value and an upper limit value.

In the present specification, regarding the description of a group (atomic group), in a case where whether the group is substituted or unsubstituted is not described, the group includes a group which has a substituent as well as a group which does not have a substituent. For example, an “alkyl group” includes not only an alkyl group (unsubstituted alkyl group) which does not have a substituent but also an alkyl group (substituted alkyl group) which has a substituent.

In addition, in the present specification, “actinic rays” or “radiation” refers to, for example, far ultraviolet rays, extreme ultraviolet rays (EUV: extreme ultraviolet lithography), X-rays, electron beams, and the like. Moreover, in the present specification, “light” refers to actinic rays and radiation. In the present specification, unless otherwise specified, “exposure” includes not only exposure with far ultraviolet rays, X-rays, EUV light, or the like but also lithography by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, “ppm” means “parts-per-million (10⁻⁶)”, “ppb” means “parts-per-billion (10⁻⁹)”, and “ppt” means “parts-per-trillion (10⁻¹²)”.

In addition, in the present specification, a weight-average molecular weight (Mw) is a value in terms of polystyrene, as measured by a gel permeation chromatography (GPC) method.

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID×15 cm) are used as columns, and tetrahydrofuran (THF) is used as an eluent.

[Light-Shielding Composition]

A light-shielding composition (hereinafter, simply described as a “composition” as well) according to an embodiment of the present invention contains a black coloring material, a resin, a polymerizable compound, a polymerization initiator, and particles.

A particle diameter of each of the particles is equal to or greater than 1 nm and less than 100 nm.

A mass ratio (hereinafter, described as a “specific ratio” as well) of a content of the particles to a content of the black coloring material is 0.01 to 0.25.

The mechanism by which the objects of the present invention are achieved with the composition having the constitution described above is not always clear, but the present inventors presume as follows.

It is considered that by adding particles (hereinafter, described as “specific particles” as well) having a particle diameter equal to or greater than 1 nm and less than 100 nm in an amount which is within the range of the aforementioned specific ratio, in a coating film formed of the composition, the specific particles move to a surface side, and a layer in which the specific particles are unevenly distributed is formed on a surface side in a cured film. It is presumed that a low-reflection effect due to interference of reflected light is obtained by the layer in which the specific particles are present in a high concentration, a low-reflection effect due to scattering of reflected light is obtained by forming fine roughnesses on the surface of the cured film due to the specific particles, and as a result, these synergistic effects improve low-reflection properties of the cured film.

Moreover, it is considered that the particle diameter of the specific particles is small, the low-reflection properties are improved, the addition amount of the specific particles is decreased, and thus in-plane uniformity of the particle distribution of the specific particles is improved and in-plane uniformity of the reflectivity of the cured film is improved.

Furthermore, it is considered that by specifying the specific ratio within a predetermined range, a low-reflection effect is obtained in the layer in which the specific particles are unevenly distributed and which is provided on the surface side, a light-shielding effect due to a black coloring material is obtained in the layer on the substrate side of the cured film, and thus both improvement in light-shielding properties and improvement in low-reflection properties are achieved.

[Black Coloring Material]

The composition according to the embodiment of the present invention contains a black coloring material.

Examples of the black coloring material include one or more selected from the group consisting of a black pigment and a black dye.

One black coloring material may be used singly or two or more black coloring materials may be used.

A content of the black coloring material in the composition is not particularly limited, but from the viewpoint that light-shielding properties are superior, is preferably equal to or greater than 30% by mass, more preferably equal to or greater than 40% by mass, even more preferably greater than 50% by mass, and particularly preferably equal to or greater than 55% by mass, with respect to a total solid content of the light-shielding composition. The upper limit of the content of the black coloring material is not particularly limited, but is preferably equal to or less than 90% by mass, more preferably equal to or less than 70% by mass, and even more preferably equal to or less than 60% by mass.

In the present specification, the “total solid content” of the composition refers to components forming a cured film, and refers to all components except a solvent in a case where the composition contains the solvent (an organic solvent, water, or the like). Moreover, in a case where the components are components forming a cured film, the components are considered to be solid contents even in a case where the components are liquid components.

Furthermore, a black coloring material obtained by combining a plurality of colorants, each of which cannot be used as a black coloring material, and adjusting the combination to be black as a whole may be used.

For example, a combination of a plurality of pigments, each of which has a color other than a black color, may be used as a black pigment. Similarly, a combination of a plurality of dyes, each of which has a color other than a black color, may be used as a black dye, and a combination of a pigment having a color other than a black color alone and a dye having a color other than a black color alone may be used as a black dye.

In the present specification, the “black coloring material” refers to a coloring material which has absorption over the entire wavelength range of 400 to 700 nm.

More specifically, for example, a black coloring material, which conforms to an evaluation standard Z described below, is preferable.

First, a composition which contains a coloring material, a transparent resin matrix (acrylic resin or the like), and a solvent, and in which a content of the coloring material with respect to the total solid content is 60% by mass is prepared. A coating film is formed by applying the obtained composition onto a glass substrate so that a film thickness of the coating film after drying is 1 μm. The light-shielding properties of the coating film after drying are evaluated using a spectrophotometer (UV-3600 manufactured by Shimadzu Corporation, or the like). In a case where the maximum value of a transmittance of the coating film after drying is less than 10% at wavelengths of 400 to 700 nm, the coloring material can be determined to be a black coloring material conforming to the evaluation standard Z.

<Black Pigment>

As a black pigment, various known black pigments can be used. The black pigment may be an inorganic pigment or an organic pigment.

As the black coloring material, from the viewpoint that the light resistance of the cured film is superior, a black pigment is preferable.

The black pigment is preferably a pigment which alone develops a black color, and more preferably a pigment which alone develops a black color and absorbs infrared rays.

Here, the black pigment which absorbs infrared rays has absorption in a wavelength range of an infrared range (preferably, wavelengths of 650 to 1,300 nm), for example. A black pigment having a maximum absorption wavelength in a wavelength range of wavelengths of 675 to 900 nm is also preferable.

A particle diameter of the black pigment is not particularly limited, but is preferably 5 to 100 nm, more preferably 5 to 50 nm, and even more preferably 5 to 30 nm, from the viewpoint that a balance between handleability and the temporal stability (a black pigment is not precipitated) of the composition is superior.

In addition, the “particle diameter” in the present specification refers to an average primary particle diameter of particles measured by the following method. The average primary particle diameter can be measured using a transmission electron microscope (TEM). As the transmission electron microscope, for example, a transmission microscope HT7700 manufactured by Hitachi High-Technologies Corporation can be used.

A maximum length (Dmax: a maximum length between two points on a contour of the particle image) and a length vertical to the maximum length (DV-max: in a case where an image is sandwiched between two straight lines parallel to the maximum length, the shortest length that vertically connects the two straight lines) of the particle image obtained using the transmission electron microscope are measured, and a geometric mean value thereof (Dmax×DV-max)^{1/2} is taken as a particle diameter. Particle diameters of 100 particles are measured by this method, and an arithmetic mean value thereof is taken as an average primary particle diameter of particles.

(Inorganic Pigment)

The inorganic pigment is not particularly limited as long as the inorganic pigment has light-shielding properties and is a particle containing an inorganic compound, and known inorganic pigments can be used.

From the viewpoint that the low-reflection properties and the light-shielding properties of the cured film are superior, an inorganic pigment is preferable as the black coloring material.

Examples of the inorganic pigment include a metal oxide, a metal nitride, and a metal oxynitride which contain a metallic element of group 4 such as titanium (Ti) and zirconium (Zr), a metallic element of group 5 such as vanadium (V) and niobium (Nb), or one or more metallic elements selected from the group consisting of cobalt (Co), chromium (Cr), copper (Cu), manganese (Mn), ruthenium (Ru), iron (Fe), nickel (Ni), tin (Sn), and silver (Ag).

As the metal oxide, the metal nitride, and the metal oxynitride, particles in which other atoms are further mixed may be used. For example, metal nitride-containing particles, which further contain an atom (preferably, an oxygen atom and/or a sulfur atom) selected from elements of groups 13 to 17 of the periodic table, can be used.

A method for producing the metal nitride, metal oxide, or metal oxynitride is not particularly limited as long as a black pigment having desired physical properties can be obtained, and known production methods such as a gas-phase reaction method can be used. Examples of the gas-phase reaction method include an electric furnace method and a thermal plasma method, but from the viewpoints that few impurities are mixed in, particle diameters are easily uniform, and productivity is high, a thermal plasma method is preferable.

The metal nitride, metal oxide, or metal oxynitride may be subjected to a surface modification treatment. For example, the metal nitride, metal oxide, or metal oxynitride may be subjected to a surface modification treatment with a surface-treating agent having both a silicone group and an alkyl group. Examples of such inorganic particles include “KTP-09” series (produced by Shin-Etsu Chemical Co., Ltd.).

Among them, from the viewpoint that the generation of undercut in a case of forming a cured film can be suppressed, a nitride or an oxynitride of at least one metal selected from the group consisting of titanium, vanadium, zirconium, and niobium is more preferable. Moreover, from the viewpoint that moisture resistance of the cured film is superior, an oxynitride of at least one metal selected from the group consisting of titanium, vanadium, zirconium, and niobium is even more preferable, and titanium oxynitride (titanium black) is particularly preferable.

The titanium black is black particles containing titanium oxynitride. A surface of the titanium black can be modified, if necessary, for the purpose of improving dispersibility and suppressing aggregating properties. The titanium black can be coated with silicon oxide, titanium oxide, germanium oxide, aluminum oxide, magnesium oxide, or zirconium oxide, and can also be treated with a water-repellent substance as described in JP2007-302836A.

Examples of a method for producing the titanium black include a method (JP1974-005432A (JP-549-005432A) for heating and reducing a mixture of titanium dioxide and titanium metal in a reduction atmosphere, a method (JP1982-205322A (JP-557-205322A) for reducing ultrafine titanium dioxide obtained by hydrolyzing titanium tetrachloride at a high temperature in a reduction atmosphere containing hydrogen, a method (JP1985-065069A (JP-S60-065069A) and JP1986-201610A (JP-S61-201610A)) for reducing titanium dioxide or titanium hydroxide at a high temperature in the presence of ammonia, and a method (JP1986-201610A (JP-S61-201610A)) for attaching a vanadium compound to titanium dioxide or titanium hydroxide, and reducing the resultant at a high temperature in the presence of ammonia, but the production method is not limited to these examples.

A particle diameter of the titanium black is not particularly limited, but is preferably 10 to 45 nm and more preferably 12 to 20 nm. A specific surface area of the titanium black is not particularly limited, but in order for water repellency after a surface treatment with a water repelling agent to have a predetermined performance, a value measured by the Brunauer-Emmett-Teller (BET) method is preferably 5 to 150 m²/g and more preferably 20 to 100 m²/g.

Examples of commercial products of the titanium black include TITANIUM BLACK 105, 12S, 13R, 13M, 13M-C, 13R, 13R-N, and 13M-T (trade name, produced by Mitsubishi Materials Corporation), Tilack D (trade name, produced by AKO KASEI CO., LTD.), and MT-150A (trade name, produced by TAYCA).

It is also preferable that the composition contains titanium black in a form of a substance to be dispersed containing titanium black and a Si atom. In this form, the titanium black is contained as a substance to be dispersed in the composition. A content ratio (Si/Ti) of a Si atom to a Ti atom in the substance to be dispersed is preferably 0.05 to 0.5 and more preferably 0.07 to 0.4, in terms of mass. Here, the substance to be dispersed includes both titanium black which is in a state of primary particles and titanium black which is in a state of an aggregate (secondary particles).

Furthermore, in a case where Si/Ti of the substance to be dispersed is too small, residues tend to remain in a removal part in a case where a coating film using the substance to be dispersed is patterned by optical lithography or the like, and in a case where Si/Ti of the substance to be dispersed is too large, a light-shielding ability tends to be decreased.

In order to change Si/Ti of the substance to be dispersed (for example, to be equal to or greater than 0.05), the following means can be used. First, a dispersion is obtained by dispersing titanium oxide and silica particles using a disperser, this mixture is subjected to a reduction treatment at a high temperature (for example, 850° C. to 1,000° C.), and thus a substance to be dispersed, which has titanium black particles as a main component and contains Si and Ti, can be obtained. The titanium black having adjusted Si/Ti can be produced, for example, by the method described in paragraphs 0005 and 0016 to 0021 of JP2008-266045A.

Furthermore, the content ratio (Si/Ti) of a Si atom to a Ti atom in the substance to be dispersed can be measured, for example, using the method (2-1) or the method (2-3) described in paragraphs 0054 to 0056 of WO2011/049090A.

In the substance to be dispersed containing titanium black and a Si atom, the aforementioned titanium black can be used. Moreover, in this substance to be dispersed, for the purpose of adjusting dispersibility, colorability, or the like, one black pigment, which consists of a complex oxide of a plurality of metals selected from Cu, Fe, Mn, V, Ni, and the like, cobalt oxide, iron oxide, carbon black, aniline black, and the like, or a combination of two or more black pigments may be used as a substance to be dispersed in combination with the titanium black. In this case, it is preferable that a substance to be dispersed consisting of titanium black accounts for equal to or greater than 50% by mass of the total substance to be dispersed.

It is also preferable to use zirconium nitride and zirconium oxynitride. The zirconium nitride and the zirconium oxynitride are preferably coated with an inorganic compound. By coating the surface through the coating with an inorganic compound, a photocatalytic activity of the light-shielding pigment is suppressed without impairing the light-shielding properties of the light-shielding pigment, and deterioration of the light-shielding composition is easily prevented. Specific examples of the inorganic compound include titanium dioxide, zirconia, silica, and alumina, but silica and alumina are preferable. It is also preferable to use a combination, such as titanium black and zirconium nitride, titanium black and zirconium oxynitride, titanium black and silica-coated zirconium nitride, and titanium black and alumina-coated zirconium nitride.

As the inorganic pigment, carbon black is also mentioned.

Examples of the carbon black include furnace black, channel black, thermal black, acetylene black, and lamp black.

As the carbon black, carbon black produced by known methods such as an oil furnace method may be used, or a commercial product may be used. Specific examples of the commercial product of the carbon black include an organic pigment such as C. I. Pigment Black 1 and an inorganic pigment such as C. I. Pigment Black 7.

As the carbon black, carbon black subjected to a surface treatment is preferable. The surface treatment can modify a particle surface state of the carbon black, and improve dispersion stability in the composition. Examples of the surface treatment include a coating treatment with a resin, a surface treatment for introducing an acidic group, and a surface treatment with a silane coupling agent.

As the carbon black, carbon black subjected to a coating treatment with a resin is preferable. The light-shielding properties and the insulating properties of the cured film can be improved by coating a particle surface of carbon black with an insulating resin. Moreover, reliability or the like of an image display device can be improved by reducing a leakage current or the like. Therefore, the aforementioned carbon black is suitable in a case of being used in applications which require insulating properties of a cured film.

Examples of a coating resin include an epoxy resin, polyamide, polyamide imide, a novolak resin, a phenol resin, a urea resin, a melamine resin, polyurethane, a diallyl phthalate resin, an alkylbenzene resin, polystyrene, polycarbonate, polybutylene terephthalate, and modified polyphenylene oxide.

From the viewpoint that the light-shielding properties and the insulating properties of the cured film are superior, a content of the coating resin is preferably 0.1% to 40% by mass and more preferably 0.5% to 30% by mass, with respect to the total of the carbon black and the coating resin.

(Organic Pigment)

The organic pigment is not particularly limited as long as the organic pigment has light-shielding properties and is a particle containing an organic compound, and known organic pigments can be used.

In the present invention, examples of the organic pigment include a bisbenzofuranone compound, an azomethine compound, a perylene compound, and an azo-based compound, and a bisbenzofuranone compound or a perylene compound is preferable.

Examples of the bisbenzofuranone compound include the compounds described in JP2010-534726A, JP2012-515233A, and JP2012-515234A. The bisbenzofuranone compound is available as “Irgaphor Black” (trade name) produced by BASF SE.

Examples of the perylene compound include the compounds described in JP1987-001753A (JP-562-001753A) and JP1988-026784B (JP-563-026784B). The perylene compound is available as C. I. Pigment Black 21, 30, 31, 32, 33, and 34.

<Black Dye>

As a black dye, a dye which alone develops a black color can be used, and for example, a pyrazole azo compound, a pyrromethene compound, an anilino azo compound, a triphenylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, and the like can be used.

Moreover, regarding the black dye, reference can be made to the compounds described in JP1989-090403A (JP-S64-090403A), JP1989-091102A (JP-S64-091102A), JP1989-094301A (JP-H01-094301A), JP1994-011614A (JP-H06-011614A), JP2592207B, U.S. Pat. Nos. 4,808,501A, 5,667,920A, US0505950A, JP1993-333207A (JP-H05-333207A), JP1994-035183A (JP-H06-035183A), JP1994-051115A (JP-H06-051115A), JP1994-194828A (JP-H06-194828A), and the like, the contents of which are incorporated into the present specification.

Specific examples of these black dyes include dyes specified by Color Index (C. I.) of SOLVENT BLACK 27 to 47, and a dye specified by C. I. of SOLVENT BLACK 27, 29, or 34 is preferable.

Furthermore, examples of commercial products of these black dyes include dyes such as SPILON Black MH and Black BH (both produced by Hodogaya Chemical Co., Ltd.), VALIFAST Black 3804, 3810, 3820, and 3830 (all produced by Orient Chemical Industries Co., Ltd.), Savinyl Black RLSN (produced by Clariant), and KAYASET Black K-R and K-BL (both produced by Nippon Kayaku Co., Ltd.).

In addition, a coloring agent multimer may be used as the black dye. Examples of the coloring agent multimer include the compounds described in JP2011-213925A and JP2013-041097A. Moreover, a polymerizable dye having polymerizability group in a molecule may be used, and examples of a commercial product thereof include RDW series produced by FUJIFILM Wako Pure Chemical Corporation.

Furthermore, as described above, a combination of a plurality of dyes, each of which has a color other than a black color, may be used as a black dye. As such a coloring dye, for example, the dye described in paragraphs 0027 to 0200 of JP2014-042375A can also be used in addition to a dye (chromatic dye) having a chromatic color such as red (R), green (G), and blue (B).

(Colorant)

The composition according to the embodiment of the present invention may contain a colorant in addition to the black coloring material. The light-shielding characteristics of the cured film (light-shielding film) can be adjusted by using both the black coloring material and one or more colorants. Moreover, for example, in a case where the cured film is used as a light-attenuating film, respective wavelengths of light containing a wide wavelength component are likely to be uniformly attenuated.

Examples of the colorant include pigments and dyes other than the aforementioned black coloring materials.

In a case where the composition contains the colorant, the total content of the black coloring material and the colorant is preferably 10% to 90% by mass, more preferably 30% to 70% by mass, and even more preferably 40% to 60% by mass, with respect to the total mass of the solid contents of the composition.

Furthermore, in a case where the cured film formed of the composition according to the embodiment of the present invention is used as a light-attenuating film, it is also preferable that the total content of the black coloring material and the colorant is less than the above suitable range.

Moreover, a mass ratio (content of colorant/content of black coloring material) of the content of the colorant to the content of the black coloring material is preferably 0.1 to 9.0.

(Infrared Absorber)

The composition may further contain an infrared absorber.

The infrared absorber refers to a compound having absorption in a wavelength range of an infrared range (preferably, wavelengths of 650 to 1,300 nm). The infrared absorber is preferably a compound having a maximum absorption wavelength in a wavelength range of wavelengths of 675 to 900 nm.

Examples of a colorant having such spectral characteristics include a pyrrolopyrrole compound, a copper compound, a cyanine compound, a phthalocyanine compound, an iminium compound, a thiol complex-based compound, a transition metal oxide-based compound, a squarylium compound, a naphthalocyanine compound, a quaterrylene compound, a dithiol metal complex-based compound, and a croconium compound.

As the phthalocyanine compound, the naphthalocyanine compound, the iminium compound, the cyanine compound, the squarylium compound, and the croconium compound, the compounds disclosed in paragraphs 0010 to 0081 of JP2010-111750A may be used, the contents of which are incorporated into the present specification. Regarding the cyanine compound, reference can be made to, for example, “Functional Dyes, written by Makoto OKAWARA, Masaru MAT SUOKA, Teijiro KITAO, and Tsuneaki HIRASHIMA, Kodansha Scientific Ltd.”, the contents of which are incorporated into the specification of the present application.

As the colorant having the spectral characteristics, the compound disclosed in paragraphs 0004 to 0016 of JP1995-164729A (JP-H07-164729A) and/or the compound disclosed in paragraphs 0027 to 0062 of JP2002-146254A, and the near-infrared absorption particles which are disclosed in paragraphs 0034 to 0067 of JP2011-164583A, consist of crystallites of an oxide containing Cu and/or P, and have a number-average aggregated particle diameter of 5 to 200 nm can be used.

As the compound having a maximum absorption wavelength in a wavelength range of wavelengths of 675 to 900 nm, at least one selected from the group consisting of a cyanine compound, a pyrrolopyrrole compound, a squarylium compound, a phthalocyanine compound, and a naphthalocyanine compound is preferable.

Furthermore, the infrared absorber is preferably a compound which is dissolved in an amount equal to or greater than 1% by mass in water at 25° C., and more preferably a compound which is dissolved in an amount equal to or greater than 10% by mass in water at 25° C. By using such a compound, solvent resistance is improved.

Regarding the pyrrolopyrrole compound, reference can be made to paragraphs 0049 to 0062 of JP2010-222557A, the contents of which are incorporated into the present specification. Regarding the cyanine compound and the squarylium compound, reference can be made to paragraphs 0022 to 0063 of WO2014/088063A, paragraphs 0053 to 0118 of WO2014/030628A, paragraphs 0028 to 0074 of JP2014-059550A, paragraphs 0013 to 0091 of WO2012/169447A, paragraphs 0019 to 0033 of JP2015-176046A, paragraphs 0053 to 0099 of JP2014-063144A, paragraphs 0085 to 0150 of JP2014-052431A, paragraphs 0076 to 0124 of JP2014-044301A, paragraphs 0045 to 0078 of JP2012-008532A, paragraphs 0027 to 0067 of JP2015-172102A, paragraphs 0029 to 0067 of JP2015-172004A, paragraphs 0029 to 0085 of JP2015-040895A, paragraphs 0022 to 0036 of JP2014-126642A, paragraphs 0011 to 0017 of JP2014-148567A, paragraphs 0010 to 0025 of JP2015-157893A, paragraphs 0013 to 0026 of JP2014-095007A, paragraphs 0013 to 0047 of JP2014-080487A, paragraphs 0007 to 0028 of JP2013-227403A, and the like, the contents of which are incorporated into the present specification.

[Particles]

The composition according to the embodiment of the present invention contains particles having a particle diameter equal to or greater than 1 nm and less than 100 nm.

The specific ratio in the composition according to the embodiment of the present invention is 0.01 to 0.25.

Moreover, different materials are used for specific particles and the black coloring material.

The specific ratio is preferably greater than 0.01, more preferably equal to or greater than 0.03, and even more preferably equal to or greater than 0.04, from the viewpoint that the low-reflection properties, the in-plane uniformity, and the light-shielding properties of the cured film are superior.

Moreover, the specific ratio is preferably less than 0.25 and more preferably equal to or less than 0.20, from the viewpoint that the in-plane uniformity of the cured film is superior. The specific ratio is even more preferably equal to or less than 0.15 from the viewpoint that the light-shielding properties and the moisture resistance of the cured film are superior, and is particularly preferably equal to or less than 0.125 from the viewpoint that the light-shielding properties of the cured film are superior.

A content of the specific particles in the composition is not particularly limited as long as the content satisfies the above range of the specific ratio, but from the viewpoint that the reflection characteristics of the cured film are superior, is preferably 0.1% to 16% by mass, more preferably greater than 1% by mass and less than 10% by mass, even more preferably 2% to 8% by mass, and particularly preferably 2% to 6% by mass, with respect to the total solid content of the composition.

In some cases, the content of the specific particles is preferably less than 5% by mass and more preferably less than 4% by mass, with respect to the total solid content of the composition. In this case, the lower limit is not particularly limited, but is preferably equal to or greater than 0.1% by mass and more preferably greater than 1% by mass.

A particle diameter of each of the specific particles is equal to or greater than 1 nm and less than 100 nm.

As described above, by using the specific particles having a particle diameter equal to or greater than 1 nm and less than 100 nm, the low-reflection properties, the in-plane uniformity, and the light-shielding properties of the cured film can all be improved. Moreover, by using the specific particles having a particle diameter equal to or greater than 1 nm and less than 100 nm, the light resistance and the moisture resistance of the cured film can also be improved.

The particle diameter of each of the specific particles is preferably 1 to 90 nm, more preferably 10 to 80 nm, and even more preferably 20 to 60 nm, from the viewpoint that a balance between the improvement in each characteristic of the cured film and the handleability is superior.

A refractive index of each of the specific particles is not particularly limited, but is preferably 1.10 to 1.40 and more preferably 1.15 to 1.35, from the viewpoint that the low-reflection properties of the cured film are superior.

Examples of the specific particles include inorganic particles, organic particles, and inorganic-organic composite particles, and a mixture of two or more thereof may be used.

Examples of an inorganic compound constituting the inorganic particles include an inorganic oxide, an inorganic nitride, an inorganic carbide, carbonate, sulfate, silicate, phosphate, and a composite of two or more thereof, an inorganic oxide, an inorganic nitride, or carbonate is preferable, and an inorganic oxide is more preferable.

The inorganic compound preferably contains at least one metal selected from the group consisting of silicon, titanium, and aluminum, more preferably contains silicon or titanium, and even more preferably contains silicon.

Specific examples of the inorganic particles include silica (silicon dioxide), titania (titanium dioxide), alumina (aluminum oxide), a mica compound, zinc oxide, zircon oxide, tin oxide, potassium titanate, strontium titanate, aluminum borate, magnesium oxide, magnesium borate, aluminum hydroxide, magnesium hydroxide, calcium hydroxide, titanium hydroxide, basic magnesium sulfate, calcium carbonate, magnesium carbonate, calcium sulfate, magnesium sulfate, calcium silicate, magnesium silicate, calcium phosphate, silicon nitride, titanium nitride, aluminum nitride, silicon carbide, titanium carbide, and zinc sulfide.

Among them, silica, titania, alumina, a mica compound, glass, potassium titanate, strontium titanate, aluminum borate, magnesium oxide, calcium carbonate, magnesium carbonate, calcium silicate, magnesium silicate, calcium phosphate, or calcium sulfate is preferable, and silica, titania, alumina, or calcium carbonate is more preferable.

Examples of an organic compound constituting the organic particles include a resin, and specific examples thereof include a synthetic resin and a natural polymer.

Examples of the synthetic resin and the natural polymer include an acrylic resin, polyethylene, polypropylene, polyethylene oxide, polypropylene oxide, polyethylene imine, polystyrene, polyurethane, polyurea, polyester, polyamide, polyimide, carboxymethyl cellulose, gelatin, starch, chitin, and chitosan, and among them, an acrylic resin, polyethylene, polypropylene, or polystyrene is preferable, and an acrylic resin is more preferable. Specific examples of a commercial product suitable as the organic particles include EPOSTAR MX020W, MX030W, and MX050W (all produced by NIPPON SHOKUBAI CO., LTD.).

As the specific particles, particles containing an inorganic oxide, an inorganic nitride, carbonate, or a resin are preferable.

Moreover, as the specific particles, from the viewpoint that the in-plane uniformity of the reflectivity in the cured film is superior, inorganic oxide particles or resin particles are preferable, and from the viewpoint that the light resistance and the moisture resistance of the cured film are superior, inorganic oxide particles are more preferable.

The specific particles preferably contain, as the inorganic oxide, at least one selected from the group consisting of silica, titania, and alumina.

A shape of each of the specific particles is not particularly limited, examples thereof include a fibrous shape, a needle shape, a plate shape, a spherical shape, a tetrapod shape, and a balloon shape, and a spherical shape is preferable.

Moreover, the specific particles may be monodisperse particles, or may be aggregated particles as long as the particles satisfy a predetermined particle diameter.

Furthermore, the specific particles may be particles (hollow particles) having a hollow structure, or may be particles having no hollow structure.

In the present specification, the hollow structure refers to a structure consisting of an inner cavity and an outer shell surrounding the cavity.

As the specific particles, from the viewpoint that the low-reflection properties of the cured film are superior, particles having a hollow structure are preferable.

The reason why the hollow particles improve the low-reflection properties of the cured film is not restricted by a theory, but is considered as follows.

It is considered that since the hollow particles have a cavity inside, and have a lower specific gravity compared to particles having no hollow structure, the hollow particles float on the surface of the coating film formed of the composition, and thus the effect of being unevenly distributed on the surface of the cured film is further enhanced.

Furthermore, the hollow particles have a lower refractive index compared to the particles having no hollow structure. For example, in a case where the hollow particles are formed of silica, the hollow silica particles have air having a low refractive index (refractive index=1.0), and thus the refractive index of the particles is 1.2 to 1.4, which is significantly lower compared to normal silica (refractive index=1.6). Therefore, it is considered that by forming the cured film using the composition containing the hollow particles, the hollow particles having a low refractive index are unevenly distributed on the surface of the cured film, an anti-reflection (AR)-type low-reflection effect is obtained, and the low-reflection properties of the cured film are improved.

Examples of the hollow particles include the hollow silica particles described in JP2001-233611A and JP3272111B.

As the specific particles, rosary-like silica particles which are particle aggregates in which a plurality of silica particles are connected in a chain shape may be used. As the rosary-like silica particles, particles in which a plurality of spherical colloidal silica particles having an average particle diameter of 5 to 50 nm are bonded to each other with metal oxide-containing silica are preferable.

Examples of the rosary-like colloidal silica particles include the silica sols described in JP4328935B and JP2013-253145A.

[Resin]

The composition according to the embodiment of the present invention contains a resin. Examples of the resin include a dispersant and an alkali-soluble resin.

A content of the resin in the composition is not particularly limited, but is preferably 3% to 60% by mass, more preferably 10% to 40% by mass, and even more preferably 15% to 35% by mass, with respect to the total solid content of the composition. The resins may be used singly or in combination of two or more thereof. For example, as the resin, a dispersant, which will be described later, and an alkali-soluble resin, which will be described later, may be used in combination. In a case where two or more resins are used in combination, the total content thereof is preferably within the above range.

Furthermore, a molecular weight of the resin is greater than 2,000. Moreover, in a case where the molecular weight of the resin is polydisperse, a weight-average molecular weight thereof is greater than 2,000.

<Dispersant>

The composition preferably contains a dispersant. Moreover, in the present specification, a dispersant refers to a compound different from the alkali-soluble resin which will be described later.

A content of the dispersant in the composition is not particularly limited, but is preferably 2% to 40% by mass, more preferably 5% to 30% by mass, and even more preferably 10% to 20% by mass, with respect to the total solid content of the composition. The dispersants may be used singly or in combination of two or more thereof. In a case where two or more dispersants are used in combination, the total content thereof is preferably within the above range.

Furthermore, in the composition, a mass ratio (content of dispersant/content of black coloring material) of the content of the dispersant (preferably, a graft polymer) to the content of the black coloring material is preferably 0.05 to 1.00, more preferably 0.05 to 0.35, and even more preferably 0.20 to 0.35.

As the dispersant, for example, known dispersants can be appropriately selected and used. Among them, a polymer compound is preferable.

Examples of the dispersant include a polymer dispersant [for example, polyamidoamine and a salt thereof, polycarboxylic acid and a salt thereof, high-molecular-weight unsaturated acid ester, modified polyurethane, modified polyester, modified poly(meth)acrylate, a (meth)acrylic copolymer, and a naphthalenesulfonic acid-formalin condensate], polyoxyethylene alkyl phosphoric acid ester, polyoxyethylene alkylamine, and a pigment derivative.

The polymer compound can be further classified into a linear polymer, a terminal-modified polymer, a graft polymer, and a block polymer based on the structure.

⋅ Polymer Compound

The polymer compound acts to prevent the reaggregation of a substance to be dispersed by being adsorbed onto a surface of the substance to be dispersed, such as the black pigment and another pigment (hereinafter, the black pigment and the other pigment are collectively and simply described as a “pigment” as well) used in combination if desired. Therefore, a terminal-modified polymer, a graft (containing a polymer chain) polymer, or a block polymer is preferable which contains a moiety anchored to the pigment surface.

The polymer compound may contain a curable group.

Examples of the curable group include an ethylenically unsaturated group (for example, a (meth)acryloyl group, a vinyl group, a styryl group, and the like), and a cyclic ether group (for example, an epoxy group, an oxetanyl group, and the like), but the present invention is not limited to these examples.

Among them, from the viewpoint that polymerization can be controlled by a radical reaction, as the curable group, an ethylenically unsaturated group is preferable, and a (meth)acryloyl group is more preferable.

The resin containing a curable group preferably has at least one selected from the group consisting of a polyester structure and a polyether structure. In this case, the polyester structure and/or the polyether structure may be included in a main chain, and as will be described later, in a case where the resin has a structural unit containing a graft chain, the polymer chain may have a polyester structure and/or a polyether structure.

As the resin, a resin in which the polymer chain has a polyester structure is more preferable.

The polymer compound preferably has a structural unit containing a graft chain. Moreover, in the present specification, the “structural unit” has the same definition as a “repeating unit”.

Such a polymer compound having the structural unit containing a graft chain has an affinity with a solvent due to the graft chain, and thus is excellent in dispersibility of a pigment or the like and dispersion stability (temporal stability) after the lapse of time. Moreover, due to the presence of the graft chain, the polymer compound having the structural unit containing a graft chain has an affinity with a polymerizable compound or other resins which can be used in combination. As a result, residues are less likely to be generated in alkali development.

In a case where the graft chain is prolonged, a steric repulsion effect is enhanced, and thus the dispersibility of the pigment or the like is improved. Meanwhile, in a case where the graft chain is too long, adsorptive power to the pigment or the like is reduced, and thus the dispersibility of the pigment or the like tends to be reduced. Therefore, the number of atoms excluding a hydrogen atom in the graft chain is preferably 40 to 10,000, more preferably 50 to 2,000, and even more preferably 60 to 500.

Herein, the graft chain refers to a portion from the base (in a group which is branched off from the main chain, an atom bonded to the main chain) of a main chain of the copolymer to the terminal of a group branched off from the main chain.

The graft chain preferably has a polymer structure, and examples of such a polymer structure include a poly(meth)acrylate structure (for example, a poly(meth)acryl structure), a polyester structure, a polyurethane structure, a polyurea structure, a polyamide structure, and a polyether structure.

In order to improve interactive properties between the graft chain and the solvent, and thus enhance the dispersibility of the pigment or the like, the graft chain is preferably a graft chain having at least one selected from the group consisting of a polyester structure, a polyether structure, and a poly(meth)acrylate structure, and more preferably a graft chain having at least one of a polyester structure or a polyether structure.

A macromonomer (a monomer which has a polymer structure and constitutes a graft chain by being bonded to the main chain of a copolymer) containing such a graft chain is not particularly limited, but a macromonomer containing a reactive double bond group can be suitably used.

As a commercial macromonomer, which corresponds to a structural unit containing a graft chain contained in the polymer compound and is suitably used for synthesizing the polymer compound, AA-6, AA-10, AB-6, AS-6, AN-6, AW-6, AA-714, AY-707, AY-714, AK-5, AK-30, and AK-32 (all are trade names, produced by TOAGOSEI CO., LTD.), and BLEMMER PP-100, BLEMMER PP-500, BLEMMER PP-800, BLEMMER PP-1000, BLEMMER 55-PET-800, BLEMMER PME-4000, BLEMMER PSE-400, BLEMMER PSE-1300, and BLEMMER 43PAPE-600B (all are trade names, produced by NOF CORPORATION) are used. Among them, AA-6, AA-10, AB-6, AS-6, AN-6, or BLEMMER PME-4000 is preferable.

The dispersant preferably has at least one structure selected from the group consisting of polymethyl acrylate, polymethyl methacrylate, and cyclic or chain-like polyester, more preferably has at least one structure selected from the group consisting of polymethyl acrylate, polymethyl methacrylate, and chain-like polyester, and even more preferably has at least one structure selected from the group consisting of a polymethyl acrylate structure, a polymethyl methacrylate structure, a polycaprolactone structure, and a polyvalerolactone structure. The dispersant may be a dispersant having the aforementioned structure alone in one dispersant, or may be a dispersant having a plurality of these structures in one dispersant.

Herein, the polycaprolactone structure refers to a structure containing a structure, which is obtained by ring opening of ε-caprolactone, as a repeating unit. The polyvalerolactone structure refers to a structure containing a structure, which is obtained by ring opening of δ-valerolactone, as a repeating unit.

Specific examples of the dispersant having a polycaprolactone structure include dispersants in which j and k in Formula (1) and Formula (2) are each 5. Moreover, specific examples of the dispersant having a polyvalerolactone structure include dispersants in which j and k in Formula (1) and Formula (2) are each 4.

Specific examples of the dispersant having a polymethyl acrylate structure include dispersants in which in Formula (4), X⁵ is a hydrogen atom and R⁴ is a methyl group. Moreover, specific examples of the dispersant having a polymethyl methacrylate structure include dispersants in which in Formula (4), X⁵ is a methyl group and R⁴ is a methyl group.

⋅ Structural unit containing graft chain

As the structural unit containing a graft chain, the polymer compound preferably has a structural unit represented by any one of Formula (1), . . . , or Formula (4), and more preferably has a structural unit represented by any one of Formula (1A), Formula (2A), Formula (3A), Formula (3B), or Formula (4).

[chemical structure]

In Formulae (1) to (4), W², W³, and W⁴ each independently represent an oxygen atom or NH. W¹, W², W³, and W⁴ are each preferably an oxygen atom.

In Formulae (1) to (4), X¹, X², X³, X⁴, and X⁵ each independently represent a hydrogen atom or a monovalent organic group. From the viewpoint of the restriction on synthesis, X¹, X², X³, X⁴, and X⁵ are preferably each independently a hydrogen atom or an alkyl group having 1 to 12 carbon atoms (the number of carbon atoms), more preferably each independently a hydrogen atom or a methyl group, and even more preferably each independently a methyl group.

In Formulae (1) to (4), Y¹, Y², Y³, and Y⁴ each independently represent a divalent linking group, and the linking group has no particular restriction on a structure. Specific examples of the divalent linking groups represented by Y¹, Y², Y³, and Y⁴ include linking groups represented by the following (Y-1) to (Y-21). In the following structures, A and B mean moieties bonded to the left terminal group and the right terminal group in Formulae (1) to (4), respectively. Among the following structures, from the viewpoint of simplicity of synthesis, (Y-2) or (Y-13) is more preferable.

[chemical structure]

[chemical structure]

[chemical structure]

In Formulae (1) to (4), Z¹, Z², Z³, and Z⁴ each independently represent a monovalent organic group. The structure of the organic group is not particularly limited, but specific examples thereof include an alkyl group, a hydroxyl group, an alkoxy group, an aryloxy group, a heteroaryloxy group, an alkylthioether group, an arylthioether group, a heteroarylthioether group, and an amino group. Among them, particularly from the viewpoint of improvement in the dispersibility, the organic groups represented by Z¹, Z², Z³, and Z⁴ are each preferably a group exhibiting a steric repulsion effect, and more preferably each independently an alkyl group or alkoxy group having 5 to 24 carbon atoms, and, among them, in particular, even more preferably each independently a branched alkyl group having 5 to 24 carbon atoms, a cyclic alkyl group having 5 to 24 carbon atoms, or an alkoxy group having 5 to 24 carbon atoms. Furthermore, the alkyl group contained in the alkoxy group may be any one of linear, branched, or cyclic.

In Formulae (1) to (4), n, m, p, and q are each independently an integer of 1 to 500.

Furthermore, in Formulae (1) and (2), j and k each independently represent an integer of 2 to 8. From the viewpoints of the temporal stability and developability of the composition, j and k in Formulae (1) and (2) are each preferably an integer of 4 to 6 and more preferably 5.

In Formulae (1) and (2), n and m are each preferably an integer equal to or greater than 10 and more preferably an integer equal to or greater than 20. Moreover, in a case where the dispersant has a polycaprolactone structure and a polyvalerolactone structure, the sum of the repeating number of the polycaprolactone structure and the repeating number of the polyvalerolactone structure is preferably an integer equal to or greater than 10 and more preferably an integer equal to or greater than 20.

In Formula (3), R³ represents a branched or linear alkylene group, and is preferably an alkylene group having 1 to 10 carbon atoms and more preferably an alkylene group having 2 or 3 carbon atoms. In a case where p is 2 to 500, a plurality of R³'s may be the same as or different from each other.

In Formula (4), R⁴ represents a hydrogen atom or a monovalent organic group, and the structure of the monovalent organic group is not particularly limited. As R⁴, a hydrogen atom, an alkyl group, an aryl group, or a heteroaryl group is preferable, and a hydrogen atom or an alkyl group is more preferable. In a case where R⁴ is an alkyl group, as the alkyl group, a linear alkyl group having 1 to 20 carbon atoms, a branched alkyl group having 3 to 20 carbon atoms, or a cyclic alkyl group having 5 to 20 carbon atoms is preferable, a linear alkyl group having 1 to 20 carbon atoms is more preferable, and a linear alkyl group having 1 to 6 carbon atoms is even more preferable. In a case where q in Formula (4) is 2 to 500, a plurality of X⁵'s and a plurality of R⁴'s in the graft copolymer may be respectively the same as or different from each other.

In addition, the polymer compound may have a structural unit which contains two or more different structures and contains a graft chain. That is, the structural units which are represented by Formulae (1) to (4) and have structures different from one another may be included in a molecule of the polymer compound, and in a case where n, m, p, and q in Formulae (1) to (4) each represent an integer equal to or greater than 2, in Formulae (1) and (2), structures in which j and k are different from each other may be included in the side chain, and in Formulae (3) and (4), a plurality of R³'s, a plurality of R⁴'s, and a plurality of X⁵'s in the molecule may be respectively the same as or different from each other.

From the viewpoints of the temporal stability and developability of the composition, the structural unit represented by Formula (1) is more preferably a structural unit represented by Formula (1A).

Furthermore, from the viewpoints of the temporal stability and developability of the composition, the structural unit represented by Formula (2) is more preferably a structural unit represented by Formula (2A).

[chemical structure]

X¹, Y¹, Z¹, and n in Formula (1A) have the same definitions as X¹, and n in

Formula (1), and preferred ranges thereof are also the same. X², Y², Z², and m in Formula (2A) have the same definitions as X², Y², Z², and m in Formula (2), and preferred ranges thereof are also the same.

In addition, from the viewpoints of the temporal stability and developability of the composition, the structural unit represented by Formula (3) is more preferably a structural unit represented by Formula (3A) or (3B).

[chemical structure]

X³, Y³, Z³, and p in Formula (3A) or (3B) have the same definitions as X³, Y³, Z³, and p in Formula (3), and preferred ranges thereof are also the same.

The polymer compound more preferably has, as a structural unit containing a graft chain, the structural unit represented by Formula (1A).

The content of the structural unit (for example, the structural units represented by Formulae (1) to (4)) containing a graft chain in the polymer compound is preferably 2% to 90% by mass and more preferably 5% to 30% by mass, in terms of mass, with respect to the total mass of the polymer compound. In a case where the content of the structural unit containing a graft chain is within the above range, the dispersibility of the pigment is high and the developability in a case of forming a cured film is favorable.

⋅ Hydrophobic Structural Unit

The polymer compound preferably has a hydrophobic structural unit which is different from the structural unit (that is, does not correspond to the structural unit containing a graft chain) containing a graft chain. Here, in the present specification, the hydrophobic structural unit is a structural unit which does not have an acid group (for example, a carboxylic acid group, a sulfonic acid group, a phosphoric acid group, a phenolic hydroxyl group, or the like).

As the hydrophobic structural unit, a structural unit derived from (corresponding to) a compound (monomer) having a C log P value equal to or greater than 1.2 is preferable, and a structural unit derived from a compound having a C log P value of 1.2 to 8 is more preferable. By doing so, the effect of the present invention can be more reliably exhibited.

The C log P value is a value calculated by a program “CLOGP” available from Daylight Chemical Information System, Inc. This program provides a value of “calculated log P” calculated by the fragment approach (see the following documents) of Hansch and Leo. The fragment approach is based on a chemical structure of a compound, and the log P value of the compound is estimated by dividing the chemical structure into partial structures (fragments) and summing up degrees of contribution to log P which are assigned to the fragments. Details of the method are described in the following documents. In the present specification, a C log P value calculated by a program CLOGP v4.82 is used.

A. J. Leo, Comprehensive Medicinal Chemistry, Vol. 4, C. Hansch, P. G. Sammnens, J. B. Taylor and C. A. Ramsden, Eds., p. 295, Pergamon press, 1990, C. Hansch & A. J. Leo. Substituent Constants For Correlation Analysis in Chemistry and Biology. John Wiley & Sons. A. J. Leo. Calculating log Poct from structure. Chem. Rev., 93, 1281 to 1306, 1993.

The log P refers to a common logarithm of a partition coefficient P, is a physical property value that shows how a certain organic compound is partitioned in an equilibrium of a two-phase system consisting of oil (generally, 1-octanol) and water by using a quantitative numerical value, and is expressed by the following expression.

log P=log(Coil/Cwater)

In the expression, Coil represents a molar concentration of a compound in an oil phase, and Cwater represents a molar concentration of the compound in a water phase.

The greater the positive log P value based on 0, the higher the oil solubility, and the greater the absolute value of negative log P, the higher the water solubility. Accordingly, the value of log P has a negative correlation with the water solubility of an organic compound and is widely used as a parameter for estimating the hydrophilicity and hydrophobicity of an organic compound.

The polymer compound preferably has, as a hydrophobic structural unit, one or more structural units selected from structural units derived from monomers represented by Formulae (i) to (iii).

[chemical structure]

In Formulae (i) to (iii), R¹, R², and R³ each independently represent a hydrogen atom, a halogen atom (for example, a fluorine atom, a chlorine atom, a bromine atom, and the like), or an alkyl group (for example, a methyl group, an ethyl group, a propyl group, and the like) having 1 to 6 carbon atoms.

R¹, R², and R³ are each preferably a hydrogen atom or an alkyl group having 1 to 3 carbon atoms, and more preferably a hydrogen atom or a methyl group. R² and R³ are each even more preferably a hydrogen atom.

X represents an oxygen atom (—O—) or an imino group (—NH—), and is preferably an oxygen atom.

L is a single bond or a divalent linking group. Examples of the divalent linking group include a divalent aliphatic group (for example, an alkylene group, a substituted alkylene group, an alkenylene group, a substituted alkenylene group, an alkynylene group, or a substituted alkynylene group), a divalent aromatic group (for example, an arylene group or a substituted arylene group), a divalent heterocyclic group, an oxygen atom (—O—), a sulfur atom (—S—), an imino group (—NH—), a substituted imino group (—NR³¹—, where R³¹ is an aliphatic group, an aromatic group, or a heterocyclic group), a carbonyl group (—CO—), and a combination thereof.

The divalent aliphatic group may have a cyclic structure or a branched structure. The number of carbon atoms in the aliphatic group is preferably 1 to 20, more preferably 1 to 15, and even more preferably 1 to 10. The aliphatic group may be an unsaturated aliphatic group or a saturated aliphatic group, but is preferably a saturated aliphatic group. Moreover, the aliphatic group may have a substituent. Examples of the substituent include a halogen atom, an aromatic group, and a heterocyclic group.

The number of carbon atoms in the divalent aromatic group is preferably 6 to 20, more preferably 6 to 15, and even more preferably 6 to 10. Moreover, the aromatic group may have a substituent. Examples of the substituent include a halogen atom, an aliphatic group, an aromatic group, and a heterocyclic group.

The divalent heterocyclic group preferably contains a 5-membered ring or a 6-membered ring as a heterocyclic ring. The heterocyclic ring may be fused with another heterocyclic ring, an aliphatic ring, or an aromatic ring. Moreover, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group.

L is preferably a single bond, an alkylene group, or a divalent linking group having an oxyalkylene structure. The oxyalkylene structure is more preferably an oxyethylene structure or an oxypropylene structure. Moreover, L may have a polyoxyalkylene structure which contains two or more repeating oxyalkylene structures. As the polyoxyalkylene structure, a polyoxyethylene structure or a polyoxypropylene structure is preferable. The polyoxyethylene structure is represented by —(OCH₂CH₂)n-, and n is preferably an integer equal to or greater than 2 and more preferably an integer of 2 to 10.

Examples of Z include an aliphatic group (for example, an alkyl group, a substituted alkyl group, an unsaturated alkyl group, or a substituted unsaturated alkyl group), an aromatic group (for example, an aryl group, a substituted aryl group, an arylene group, or a substituted arylene group), a heterocyclic group, and a combination thereof. These groups may contain an oxygen atom (—O—), a sulfur atom (—S—), an imino group (—NH—), a substituted imino group (—NR³¹— where R³¹ is an aliphatic group, an aromatic group, or a heterocyclic group), or a carbonyl group (—CO—).

The aliphatic group may have a cyclic structure or a branched structure. The number of carbon atoms in the aliphatic group is preferably 1 to 20, more preferably 1 to 15, and even more preferably 1 to 10. The aliphatic group further contains a ring-aggregated hydrocarbon group or a crosslinked cyclic hydrocarbon group, and examples of the ring-aggregated hydrocarbon group include a bicyclohexyl group, a perhydronaphthalenyl group, a biphenyl group, and a 4-cyclohexylphenyl group. Examples of a crosslinked cyclic hydrocarbon ring include a bicyclic hydrocarbon ring such as pinane, bornane, norpinane, norbornane, and bicyclooctane rings (a bicyclo[2.2.2]octane ring, a bicyclo[3.2.1]octane ring, or the like); a tricyclic hydrocarbon ring such as homobredane, adamantane, tricyclo[5.2.1.0^{2,6}]decane, and tricyclo[4.3.1.1^{2,5}]undecane rings; and a tetracyclic hydrocarbon ring such as tetracyclo[4.4.0.1^{2,5}.1^{7,10}]dodecane and perhydro-1,4-methano-5,8-methanonaphthalene rings. Moreover, the crosslinked cyclic hydrocarbon ring also includes a fused cyclic hydrocarbon ring, for example, a fused ring in which a plurality of 5- to 8-membered cycloalkane rings, such as perhydronaphthalene (decalin), perhydroanthracene, perhydrophenanthrene, perhydroacenaphthene, perhydrofluorene, perhydroindene, and perhydrophenalene rings, are fused.

As the aliphatic group, a saturated aliphatic group is more preferable to an unsaturated aliphatic group. Moreover, the aliphatic group may have a substituent. Examples of the substituent include a halogen atom, an aromatic group, and a heterocyclic group. Here, the aliphatic group does not have an acid group as a substituent.

The number of carbon atoms in the aromatic group is preferably 6 to 20, more preferably 6 to 15, and even more preferably 6 to 10. Moreover, the aromatic group may have a substituent. Examples of the substituent include a halogen atom, an aliphatic group, an aromatic group, and a heterocyclic group. Here, the aromatic group does not have an acid group as a substituent.

The heterocyclic group preferably contains a 5-membered ring or a 6-membered ring as a heterocyclic ring. The heterocyclic ring may be fused with another heterocyclic ring, an aliphatic ring, or an aromatic ring. Moreover, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group. Here, the heterocyclic group does not have an acid group as a substituent.

In Formula (iii), R⁴, R⁵, and R⁶ each independently represent a hydrogen atom, a halogen atom (for example, a fluorine atom, a chlorine atom, a bromine atom, and the like), an alkyl group (for example, a methyl group, an ethyl group, a propyl group, and the like) having 1 to 6 carbon atoms, Z, or L-Z. Herein, L and Z have the same definitions as the groups described above. As R⁴, R⁵, and R⁶, a hydrogen atom or an alkyl group having 1 to 3 carbon atoms is preferable, and a hydrogen atom is more preferable.

The monomer represented by Formula (i) is preferably a compound in which R¹, R², and R³ are each a hydrogen atom or a methyl group, L is a single bond, an alkylene group, or a divalent linking group having an oxyalkylene structure, X is an oxygen atom or an imino group, and Z is an aliphatic group, a heterocyclic group, or an aromatic group.

The monomer represented by Formula (ii) is preferably a compound in which R¹ is a hydrogen atom or a methyl group, L is an alkylene group, and Z is an aliphatic group, a heterocyclic group, or an aromatic group. Moreover, the monomer represented by Formula (iii) is preferably a compound in which R⁴, R⁵, and R⁶ are each a hydrogen atom or a methyl group, and Z is an aliphatic group, a heterocyclic group, or an aromatic group.

Examples of typical compounds represented by Formulae (i) to (iii) include radically polymerizable compounds selected from acrylic acid esters, methacrylic acid esters, and styrenes.

Furthermore, regarding the examples of the typical compounds represented by Formulae (i) to (iii), reference can be made to the compounds described in paragraphs 0089 to 0093 of JP2013-249417A, the contents of which are incorporated into the present specification.

The content of the hydrophobic structural unit in the polymer compound is preferably 10% to 90% by mass and more preferably 20% to 80% by mass, in terms of mass, with respect to the total mass of the polymer compound. In a case where the content is within the above range, sufficient pattern formation can be obtained.

⋅ Functional Group Capable of Forming Interaction with Pigment or the Like

A functional group capable of forming interaction with the pigment or the like (for example, a black pigment) can be introduced into the polymer compound. Herein, it is preferable that the polymer compound further has a structural unit containing a functional group capable of forming interaction with the pigment or the like.

Examples of the functional group capable of forming interaction with the pigment or the like include an acid group, a basic group, a coordinating group, and a reactive functional group.

In a case where the polymer compound contains an acid group, a basic group, a coordinating group, or a reactive functional group, it is preferable that the polymer compound contains a structural unit containing an acid group, a structural unit containing a basic group, a structural unit containing a coordinating group, or a reactive structural unit.

In particular, in a case where the polymer compound further contains, as an acid group, an alkali-soluble group such as a carboxylic acid group, developability for forming a pattern by alkali development can be imparted to the polymer compound.

That is, in a case where an alkali-soluble group is introduced into the polymer compound, in the composition, the polymer compound as a dispersant making a contribution to the dispersion of the pigment or the like has alkali solubility. The composition containing such a polymer compound is excellent in light-shielding properties of a cured film formed by exposure, and improves alkali developability of an unexposed portion.

Furthermore, in a case where the polymer compound has a structural unit containing an acid group, the polymer compound is easily compatible with the solvent, and coating properties also tend to be improved.

It is presumed that this is because the acid group in the structural unit containing an acid group easily interacts with the pigment or the like, the polymer compound stably disperses the pigment or the like, the viscosity of the polymer compound dispersing the pigment or the like is reduced, and thus the polymer compound is also easily dispersed in a stable manner.

Here, the structural unit containing an alkali-soluble group as an acid group may be the same as or different from the structural unit containing a graft chain, but the structural unit containing an alkali-soluble group as an acid group is a structural unit different from the hydrophobic structural unit (that is, the structural unit does not correspond to the hydrophobic structural unit).

Examples of the acid group, which is the functional group capable of forming interaction with the pigment or the like, include a carboxylic acid group, a sulfonic acid group, a phosphoric acid group, and a phenolic hydroxyl group, at least one of a carboxylic acid group, a sulfonic acid group, or a phosphoric acid group is preferable, and a carboxylic acid group is more preferable. The carboxylic acid group has favorable adsorptive power to the pigment or the like and high dispersibility.

That is, it is preferable that the polymer compound further has a structural unit containing at least one of a carboxylic acid group, a sulfonic acid group, or a phosphoric acid group.

The polymer compound may have one or more structural units containing an acid group.

The polymer compound may or may not contain the structural unit containing the acid group, but in a case where the polymer compound contains the structural unit containing the acid group, the content thereof with respect to the total mass of the polymer compound is preferably 5% to 80% by mass, and more preferably 10% to 60% by mass from the viewpoint of suppressing damage of the image intensity by alkali development.

Examples of the basic group, which is the functional group capable of forming interaction with the pigment or the like, include a primary amino group, a secondary amino group, a tertiary amino group, a hetero ring containing a N atom, and an amide group, and a preferred basic group is a tertiary amino group from the viewpoints of favorable adsorptive power to the pigment or the like and high dispersibility. The polymer compound may contain one or more of these basic groups.

The polymer compound may or may not contain the structural unit containing the basic group, but in a case where the polymer compound contains the structural unit containing the basic group, the content thereof, in terms of mass, with respect to the total mass of the polymer compound is preferably 0.01% to 50% by mass, and more preferably 0.01% to 30% by mass from the viewpoint of suppressing developability inhibition.

Examples of the coordinating group and the reactive functional group, which are the functional groups capable of forming interaction with the pigment or the like, include an acetyl acetoxy group, a trialkoxysilyl group, an isocyanate group, an acid anhydride, and an acid chloride. A preferred functional group is an acetyl acetoxy group from the viewpoints of favorable adsorptive power to the pigment or the like and high dispersibility of the pigment or the like. The polymer compound may have one or more of these groups.

The polymer compound may or may not contain the structural unit containing the coordinating group or the structural unit containing the reactive functional group, but in a case where the polymer compound contains the structural unit containing the coordinating group or the structural unit containing the reactive functional group, the content thereof, in terms of mass, with respect to the total mass of the polymer compound is preferably 10% to 80% by mass, and more preferably 20% to 60% by mass from the viewpoint of suppressing developability inhibition.

In a case where the polymer compound contains, other than the graft chain, the functional group capable of forming interaction with the pigment or the like, the functional groups capable of forming interaction with various pigments or the like may be contained, the way these functional groups are introduced is not particularly limited, but it is preferable that the polymer compound has one or more structural units selected from structural units derived from monomers represented by Formulae (iv) to (vi).

[chemical structure]

In Formulae (iv) to (vi), R¹¹, R¹², and R¹³ each independently represent a hydrogen atom, a halogen atom (for example, a fluorine atom, a chlorine atom, a bromine atom, and the like), or an alkyl group (for example, a methyl group, an ethyl group, a propyl group, and the like) having 1 to 6 carbon atoms.

In Formulae (iv) to (vi), R¹¹, R¹², and R¹³ are each preferably a hydrogen atom or an alkyl group having 1 to 3 carbon atoms, and more preferably a hydrogen atom or a methyl group. In Formula (iv), R¹² and R¹³ are each even more preferably a hydrogen atom.

In Formula (iv), X₁ represents an oxygen atom (—O—) or an imino group (—NH—), and is preferably an oxygen atom.

Moreover, in Formula (v), Y represents a methine group or a nitrogen atom.

In addition, in Formulae (iv) and (v), L₁ represents a single bond or a divalent linking group. The divalent linking group has the same definition as the divalent linking group represented by L in Formula (i).

L₁ is preferably a single bond, an alkylene group, or a divalent linking group having an oxyalkylene structure. The oxyalkylene structure is more preferably an oxyethylene structure or an oxypropylene structure. Moreover, L₁ may have a polyoxyalkylene structure which contains two or more repeating oxyalkylene structures. As the polyoxyalkylene structure, a polyoxyethylene structure or a polyoxypropylene structure is preferable. The polyoxyethylene structure is represented by —(OCH₂CH₂)n-, and n is preferably an integer equal to or greater than 2 and more preferably an integer of 2 to 10.

In Formulae (iv) to (vi), Z₁ represents a functional group capable of forming interaction with the pigment or the like other than a graft chain, and is preferably a carboxylic acid group or a tertiary amino group and more preferably a carboxylic acid group.

In Formula (vi), R¹⁴, R¹⁵, and R¹⁶ each independently represent a hydrogen atom, a halogen atom (for example, a fluorine atom, a chlorine atom, a bromine atom, and the like), an alkyl group (for example, a methyl group, an ethyl group, a propyl group, and the like) having 1 to 6 carbon atoms, —Z₁, or L₁-Z₁. Herein, L₁ and Z₁ have the same definitions as L₁ and Z₁ described above, and preferred examples thereof are also the same. R¹⁴, R¹⁵, and R¹⁶ are each preferably a hydrogen atom or an alkyl group having 1 to 3 carbon atoms, and more preferably a hydrogen atom.

The monomer represented by Formula (iv) is preferably a compound in which R¹¹, R¹², and R¹³ are each independently a hydrogen atom or a methyl group, L₁ is an alkylene group or a divalent linking group having an oxyalkylene structure, X₁ is an oxygen atom or an imino group, and Z₁ is a carboxylic acid group.

Moreover, the monomer represented by Formula (v) is preferably a compound in which R¹¹ is a hydrogen atom or a methyl group, L₁ is an alkylene group, Z₁ is a carboxylic acid group, and Y is a methine group.

Furthermore, the monomer represented by Formula (vi) is preferably a compound in which R¹⁴, R¹⁵, and R¹⁶ are each independently a hydrogen atom or a methyl group, L₁ is a single bond or an alkylene group, and Z₁ is a carboxylic acid group.

Typical examples of the monomers (compounds) represented by Formulae (iv) to (vi) are shown below.

Examples of the monomers include methacrylic acid, crotonic acid, isocrotonic acid, a reaction product of a compound (for example, 2-hydroxyethyl methacrylate) containing an addition polymerizable double bond and a hydroxyl group in a molecule with a succinic acid anhydride, a reaction product of a compound containing an addition polymerizable double bond and a hydroxyl group in a molecule with a phthalic acid anhydride, a reaction product of a compound containing an addition polymerizable double bond and a hydroxyl group in a molecule with a tetrahydroxyphthalic acid anhydride, a reaction product of a compound containing an addition polymerizable double bond and a hydroxyl group in a molecule with trimellitic acid anhydride, a reaction product of a compound containing an addition polymerizable double bond and a hydroxyl group in a molecule with a pyromellitic acid anhydride, acrylic acid, an acrylic acid dimer, an acrylic acid oligomer, maleic acid, itaconic acid, fumaric acid, 4-vinylbenzoic acid, vinyl phenol, and 4-hydroxyphenyl methacrylamide.

From the viewpoints of the interaction with the pigment or the like, the temporal stability, and the permeability into a developer, the content of the structural unit containing a functional group capable of forming interaction with the pigment or the like is preferably 0.05% to 90% by mass, more preferably 1.0% to 80% by mass, and even more preferably 10% to 70% by mass, in terms of mass, with respect to the total mass of the polymer compound.

⋅ Other Structural Units

In addition, for the purpose of improving various performances such as image intensity, as long as the effects of the present invention are not impaired, the polymer compound may further have other structural units (for example, a structural unit containing a functional group or the like having an affinity with the solvent which will be described later) which have various functions and are different from the structural unit containing a graft chain, the hydrophobic structural unit, and the structural unit containing a functional group capable of forming interaction with the pigment or the like.

Examples of such other structural units include structural units derived from radically polymerizable compounds selected from acrylonitriles, methacrylonitriles, and the like.

The polymer compound may use one or more of these other structural units, and the content thereof is preferably 0% to 80% by mass and more preferably 10% to 60% by mass, in terms of mass, with respect to the total mass of the polymer compound. In a case where the content is within the above range, sufficient pattern formability is maintained.

⋅ Physical Properties of Polymer Compound

An acid value of the polymer compound is preferably 0 to 250 mg KOH/g, more preferably 10 to 200 mg KOH/g, even more preferably 30 to 180 mg KOH/g, and particularly preferably in a range of 70 to 120 mg KOH/g.

In a case where the acid value of the polymer compound is equal to or lower than 160 mg KOH/g, pattern peeling during development in a case of forming a cured film is more effectively suppressed. Moreover, in a case where the acid value of the polymer compound is equal to or higher than 10 mg KOH/g, the alkali developability is improved. Furthermore, in a case where the acid value of the polymer compound is equal to or higher than 20 mg KOH/g, the precipitation of the pigment or the like can be further suppressed, the number of coarse particles can be further reduced, and the temporal stability of the composition can be further improved.

In the present specification, the acid value can be calculated, for example, from the average content of acid groups in the compound. Moreover, a resin having a desired acid value can be obtained by changing the content of the structural unit containing an acid group, which is a constituent component of the resin.

A weight-average molecular weight of the polymer compound is preferably 4,000 to 300,000, more preferably 5,000 to 200,000, even more preferably 6,000 to 100,000, and particularly preferably 10,000 to 50,000.

The polymer compound can be synthesized based on known methods.

Specific examples of the polymer compound include “DA-7301” produced by Kusumoto Chemicals, Ltd., “Disperbyk-101 (polyamidoamine phosphate), 107 (carboxylic acid ester), 110 (copolymer containing an acid group), 111 (phosphoric acid-based dispersant), 130 (polyamide), 161, 162, 163, 164, 165, 166, 170, and 190 (polymeric copolymer)” and “BYK-P104 and P105 (high-molecular-weight unsaturated polycarboxylic acid)” produced by BYK-Chemie GmbH, “EFKA 4047, 4050 to 4010 to 4165 (based on polyurethane), EFKA 4330 to 4340 (block copolymer), 4400 to 4402 (modified polyacrylate), 5010 (polyester amide), 5765 (high-molecular-weight polycarboxylate), 6220 (fatty acid polyester), 6745 (phthalocyanine derivative), and 6750 (azo pigment derivative)” produced by EFKA, “AJISPER PB821, PB822, PB880, and PB881” produced by Ajinomoto Fine-Techno Co., Inc., “FLOWLEN TG-710 (urethane oligomer)” and “POLYFLOW No. 50E and No. 300 (acrylic copolymer)” produced by KYOEISHA CHEMICAL Co., LTD., “DISPARLON KS-860, 873SN, 874, #2150 (aliphatic polyvalent carboxylic acid), #7004 (polyether ester), DA-703-50, DA-705, and DA-725” produced by Kusumoto Chemicals, Ltd., “DEMOL RN, N (naphthalenesulfonic acid-formalin polycondensate), MS, C, and SN-B (aromatic sulfonic acid-formalin polycondensate)”, “HOMOGENOL L-18 (polymeric polycarboxylic acid)”, “EMULGEN 920, 930, 935, and 985 (polyoxyethylene nonylphenyl ether)”, and “ACETAMIN 86 (stearylamine acetate)” produced by Kao Corporation, “SOLSPERSE 5000 (phthalocyanine derivative), 22000 (azo pigment derivative), 13240 (polyester amine), 3000, 12000, 17000, 20000, 27000 (polymer containing a functional portion on a terminal portion), 24000, 28000, 32000, and 38500 (graft copolymer)” produced by Lubrizol Japan Limited, “NIKKOL T106 (polyoxyethylene sorbitan monooleate), and MYS-IEX (polyoxyethylene monostearate)” produced by Nikko Chemicals Co., Ltd., HINOACT T-8000E and the like produced by Kawaken Fine Chemicals Co., Ltd., an organosiloxane polymer KP-341 produced by Shin-Etsu Chemical Co., Ltd., “WO01: cationic surfactant”, nonionic surfactants such as polyoxyethylene lauryl ether, polyoxyethylene stearyl ether, polyoxyethylene oleyl ether, polyoxyethylene octyl phenyl ether, polyoxyethylene nonylphenyl ether, polyethylene glycol dilaurate, polyethylene glycol distearate, and a sorbitan fatty acid ester, and anionic surfactants such as “WO04, WO05, and WO17” produced by Yusho Co., Ltd., “EFKA-46, EFKA-47, EFKA-47EA, EFKA POLYMER 100, EFKA POLYMER 400, EFKA POLYMER 401, and EFKA POLYMER 450” produced by MORISHITA & CO., LTD., polymer dispersants such as “DISPERSE AID 6, DISPERSE AID 8, DISPERSE AID 15, and DISPERSE AID 9100” produced by SAN NOPCO LIMITED, “ADEKA PLURONIC L31, F38, L42, L44, L61, L64, F68, L72, P95, F77, P84, F87, P94, L101, P103, F108, L121, and P-123” produced by ADEKA CORPORATION, and “IONET (trade name) S-20” produced by Sanyo Chemical Industries, Ltd. Moreover, ACRYBASE FFS-6752 and ACRYBASE FFS-187 can also be used.

In addition, it is also preferable that an amphoteric resin containing an acid group and a basic group is used. The amphoteric resin is preferably a resin having an acid value equal to or higher than 5 mg KOH/g and an amine value equal to or higher than 5 mg KOH/g.

Examples of commercial products of the amphoteric resin include DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 produced by BYK-Chemie GmbH, and AJISPER PB821, AJISPER PB822, and AJISPER PB881 produced by Ajinomoto Fine-Techno Co., Inc.

These polymer compounds may be used singly or in combination of two or more thereof.

Furthermore, regarding specific examples of the polymer compound, reference can be made to the polymer compound described in paragraphs 0127 to 0129 of JP2013-249417A, the contents of which are incorporated into the present specification.

In addition, as the dispersant, in addition to the aforementioned polymer compounds, the graft copolymer described in paragraphs 0037 to 0115 of JP2010-106268A (corresponding to paragraphs 0075 to 0133 of US2011/0124824A) can be used, the contents of which can be incorporated by reference into the present specification.

Moreover, in addition to the aforementioned dispersant, the polymer compound, which is described in paragraphs 0028 to 0084 of JP2011-153283A (corresponding to paragraphs 0075 to 0133 of US2011/0279759A) and contains a constituent component having a side chain structure formed by bonding of acidic groups through a linking group, can be used, the contents of which can be incorporated by reference into the present specification.

Furthermore, as the dispersant, the resin described in paragraphs 0033 to 0049 of JP2016-109763A can also be used, the contents of which are incorporated into the present specification.

<Alkali-Soluble Resin>

The composition preferably contains an alkali-soluble resin. In the present specification, the alkali-soluble resin refers to a resin containing a group (an alkali-soluble group, for example, an acid group such as a carboxylic acid group) which promotes alkali solubility, and refers to a resin different from the dispersant described above.

A content of the alkali-soluble resin in the composition is not particularly limited, but is preferably 0.1% to 30% by mass, more preferably 0.5% to 20% by mass, and even more preferably 1% to 15% by mass, with respect to the total solid content of the composition.

The alkali-soluble resins may be used singly or in combination of two or more thereof. In a case where two or more alkali-soluble resins are used in combination, the total content thereof is preferably within the above range.

As the alkali-soluble resin, a resin containing at least one alkali-soluble group in a molecule is mentioned, and examples thereof include a polyhydroxystyrene resin, a polysiloxane resin, a (meth)acrylic resin, a (meth)acrylamide resin, a (meth)acryl/(meth)acrylamide copolymer resin, an epoxy-based resin, and a polyimide resin.

Specific examples of the alkali-soluble resin include a copolymer of an unsaturated carboxylic acid and an ethylenically unsaturated compound.

The unsaturated carboxylic acid is not particularly limited, but examples thereof include monocarboxylic acids such as (meth)acrylic acid, crotonic acid, and vinyl acetate; dicarboxylic acid such as itaconic acid, maleic acid, and fumaric acid or an acid anhydride thereof; and polyvalent carboxylic acid monoesters such as mono(2-(meth)acryloyloxyethyl)phthalate.

Examples of a copolymerizable ethylenically unsaturated compound include methyl (meth)acrylate. Moreover, the compounds described in paragraph 0027 of JP2010-097210A and paragraphs 0036 and 0037 of JP2015-068893A can also be used, the contents of which are incorporated into the present specification.

Furthermore, copolymerizable ethylenically unsaturated compounds containing an ethylenically unsaturated group in a side chain may be used in combination. As the ethylenically unsaturated group, a (meth)acrylic acid group is preferable. An acrylic resin containing an ethylenically unsaturated group in a side chain can be obtained, for example, by addition-reacting a carboxylic acid group of an acrylic resin containing the carboxylic acid group with an ethylenically unsaturated compound containing a glycidyl group or an alicyclic epoxy group.

As the alkali-soluble resin, an alkali-soluble resin containing a curable group is also preferable.

As the curable group, the curable groups, which may be contained in the aforementioned polymer compound, are also mentioned, and preferred ranges are also the same.

The alkali-soluble resin containing a curable group is preferably an alkali-soluble resin having a curable group in the side chain, or the like. Examples of the alkali-soluble resin containing a curable group include DIANAL NR series (produced by Mitsubishi Rayon Co., Ltd.), Photomer 6173 (COOH-containing polyurethane acrylic oligomer, produced by Diamond Shamrock Co., Ltd.), VISCOAT R-264 and KS resist 106 (all produced by OSAKA ORGANIC CHEMICAL INDUSTRY LTD.), CYCLOMER P series (for example, ACA230AA) and PLACCEL CF200 series (all produced by DAICEL CORPORATION), Ebecryl 3800 (produced by DAICEL-ALLNEX LTD.), and ACRYCURE RD-F8 (produced by NIPPON SHOKUBAI CO., LTD.).

As the alkali-soluble resin, for example, the radical polymers which contain a carboxylic acid group in a side chain and are described in JP1984-044615A (JP-559-044615A), JP1979-034327B (JP-554-034327B), JP1983-012577B (JP-558-012577B), JP1979-025957B (JP-554-025957B), JP1979-092723A (JP-554-092723A), JP1984-053836A (JP-559-053836A), and JP1984-071048A (JP-559-071048A); the acetal-modified polyvinyl alcohol-based binder resins which contain an alkali-soluble group and are described in EP993966B, EP1204000B, and JP2001-318463A; polyvinyl pyrrolidone; polyethylene oxide; polyether or the like which is a reaction product of alcohol-soluble nylon, 2,2-bis-(4-hydroxyphenyl)-propane, and epichlorohydrin; the polyimide resin described in WO2008/123097A; and the like can be used.

As the alkali-soluble resin, for example, the compound described in paragraphs 0225 to 0245 of JP2016-075845A can also be used, the contents of which are incorporated into the present specification.

As the alkali-soluble resin, a polyimide precursor can also be used. The polyimide precursor refers to a resin obtained by causing an addition polymerization reaction between a compound containing an acid anhydride group and a diamine compound at a temperature of 40° C. to 100° C.

Examples of the polyimide precursor include a resin having a repeating unit represented by Formula (1). Examples of the structure of the polyimide precursor include polyimide precursors containing an amic acid structure represented by Formula (2), and imide structures represented by Formula (3) obtained in a case where imide ring closure occurs in a portion of an amic acid structure and Formula (4) obtained in a case where imide ring closure occurs in the entirety of an amic acid structure.

Furthermore, in the present specification, the polyimide precursor having an amic acid structure is referred to as polyamic acid in some cases.

[chemical structure]

In Formulae (1) to (4), R₁ represents a tetravalent organic group having 2 to 22 carbon atoms, R₂ represents a divalent organic group having 1 to 22 carbon atoms, and n represents 1 or 2.

Specific examples of the polyimide precursor include the compound described in paragraphs 0011 to 0031 of JP2008-106250A, the compound described in paragraphs 0022 to 0039 of JP2016-122101A, and the compound described in paragraphs 0061 to 0092 of JP2016-068401A, the contents of which are incorporated into the present specification.

From the viewpoint that a pattern shape of a pattern-like cured film formed of the composition is superior, it is also preferable that the alkali-soluble resin contains at least one selected from the group consisting of a polyimide resin and a polyimide precursor.

The polyimide resin containing the alkali-soluble group is not particularly limited, and known polyimide resins containing the alkali-soluble group can be used. Examples of the polyimide resin include the resin described in paragraph 0050 of JP2014-137523A, the resin described in paragraph 0058 of JP2015-187676A, and the resin described in paragraphs 0012 and 0013 of JP2014-106326A, the contents of which are incorporated into the present specification.

As the alkali-soluble resin, a copolymer of [benzyl (meth)acrylate/(meth)acrylic acid/another addition polymerizable vinyl monomer, if necessary], and a copolymer of [allyl (meth)acrylate/(meth)acrylic acid/another addition polymerizable vinyl monomer, if necessary] are suitable because the copolymers have an excellent balance among film hardness, sensitivity, and developability.

The other addition polymerizable vinyl monomer may be used singly or two or more other addition polymerizable vinyl monomers may be used.

The copolymer preferably has a curable group and more preferably contains an ethylenically unsaturated group such as a (meth)acryloyl group, from the viewpoint that the moisture resistance of the cured film is superior.

For example, a curable group may be introduced into a copolymer by using a monomer having the curable group as the other addition polymerizable vinyl monomer. Furthermore, a curable group (preferably, an ethylenically unsaturated group such as a (meth)acryloyl group) may be introduced into a part or all of one or more of units derived from (meth)acrylic acid in the copolymer and/or units derived from the other addition polymerizable vinyl monomer.

Examples of the other addition polymerizable vinyl monomer include methyl (meth)acrylate, a styrene-based monomer (hydroxystyrene or the like), and an ether dimer.

Examples of the ether dimer include a compound represented by General Formula (ED1) and a compound represented by General Formula (ED2).

[chemical structure]

In General Formula (ED1), R¹ and R² each independently represent a hydrogen atom or a hydrocarbon group having 1 to 25 carbon atoms.

[chemical structure]

In General Formula (ED2), R represents a hydrogen atom or an organic group having 1 to 30 carbon atoms. Regarding specific examples of General Formula (ED2), reference can be made to the description of JP2010-168539A.

Regarding specific examples of the ether dimer, reference can be made to, for example, paragraph 0317 of JP2013-029760A, the contents of which are incorporated into the present specification. One ether dimer may be used singly or two or more ether dimers may be used.

An acid value of the alkali-soluble resin is not particularly limited, but is preferably 30 to 500 mg KOH/g and more preferably 50 to 200 mg KOH/g, in general.

The resin refers to a component which is dissolved in the composition and has a weight-average molecular weight greater than 2,000.

[Polymerizable Compound]

The composition according to the embodiment of the present invention contains a polymerizable compound.

In the present specification, the polymerizable compound refers to a compound which is polymerized by the action of the polymerization initiator, which will be described later, and refers to a component different from the aforementioned dispersant and alkali-soluble resin.

Moreover, the polymerizable compound refers to a component different from an epoxy group-containing compound which will be described later.

A content of the polymerizable compound in the composition is not particularly limited, but is preferably 5% to 35% by mass, more preferably 10% to 30% by mass, and even more preferably 15% to 25% by mass, with respect to the total solid content of the composition. The polymerizable compounds may be used singly or in combination of two or more thereof. In a case where two or more polymerizable compounds are used in combination, the total content thereof is preferably within the above range.

A molecular weight (or weight-average molecular weight) of the polymerizable compound is not particularly limited, but is preferably equal to or less than 2,000.

The polymerizable compound is preferably a compound which contains a group (hereinafter, simply referred to as an “ethylenically unsaturated group” as well) containing an ethylenically unsaturated bond.

That is, the composition according to the embodiment of the present invention preferably contains, as a polymerizable compound, a low-molecular-weight compound containing an ethylenically unsaturated group.

The polymerizable compound is preferably a compound containing one or more ethylenically unsaturated bonds, more preferably a compound containing two or more ethylenically unsaturated bonds, even more preferably a compound containing three or more ethylenically unsaturated bonds, and particularly preferably a compound containing five or more ethylenically unsaturated bonds. The upper limit thereof is equal to or smaller than 15, for example. Examples of the ethylenically unsaturated group include a vinyl group, a (meth)allyl group, and a (meth)acryloyl group.

As the polymerizable compound, for example, the compounds described in paragraph 0050 of JP2008-260927A and paragraph 0040 of JP2015-068893A can be used, the contents of which are incorporated into the present specification.

The polymerizable compound may be in any chemical form such as a monomer, a prepolymer, an oligomer, a mixture thereof, and a multimer thereof.

The polymerizable compound is preferably a tri- to pentadeca-functional (meth)acrylate compound, and more preferably a tri- to hexa-functional (meth)acrylate compound.

As the polymerizable compound, a compound which contains one or more ethylenically unsaturated groups and has a boiling point equal to or higher than 100° C. under normal pressure is also preferable. Reference can be made to, for example, the compounds described in paragraph 0227 of JP2013-029760A and paragraphs 0254 to 0257 of JP2008-292970A, the contents of which are incorporated into the present specification.

As the polymerizable compound, dipentaerythritol triacrylate (as a commercial product, KAYARAD D-330; produced by Nippon Kayaku Co., Ltd.), dipentaerythritol tetraacrylate (as a commercial product, KAYARAD D-320; produced by Nippon Kayaku Co., Ltd.), dipentaerythritol penta(meth)acrylate (as a commercial product, KAYARAD D-310; produced by Nippon Kayaku Co., Ltd.), dipentaerythritol hexa(meth)acrylate (as a commercial product, KAYARAD DPHA; produced by Nippon Kayaku Co., Ltd., and A-DPH-12E; produced by Shin-Nakamura Chemical Co., Ltd.), and a structure (for example, SR454 and SR499 commercially available from Sartomer) in which an ethylene glycol residue or a propylene glycol residue is between these (meth)acryloyl groups are preferable. Oligomer types thereof can also be used. Moreover, NK ESTER A-TMMT (pentaerythritol tetraacrylate, produced by Shin-Nakamura Chemical Co., Ltd.), KAYARAD RP-1040, KAYARAD DPEA-12LT, KAYARAD DPHA LT, KAYARAD RP-3060, and KAYARAD DPEA-12 (all are trade names, produced by Nippon Kayaku Co., Ltd.), and the like may be used.

The preferred aspects of the polymerizable compound are shown below.

The polymerizable compound may have an acid group such as a carboxylic acid group, a sulfonic acid group, and a phosphoric acid group. The polymerizable compound containing an acid group is preferably an ester of an aliphatic polyhydroxy compound and an unsaturated carboxylic acid, more preferably a polymerizable compound having an acid group by reacting a nonaromatic carboxylic acid anhydride with an unreacted hydroxyl group of an aliphatic polyhydroxy compound, and even more preferably a compound in which the aliphatic polyhydroxy compound in the ester is pentaerythritol and/or dipentaerythritol. Examples of a commercial product thereof include ARONIX TO-2349, M-305, M-510, and M-520 produced by TOAGOSEI CO., LTD.

The acid value of the polymerizable compound containing an acid group is preferably 0.1 to 40 mg KOH/g and more preferably 5 to 30 mg KOH/g. In a case where the acid value of the polymerizable compound is equal to or greater than 0.1 mg KOH/g, development dissolution characteristics are favorable, and in a case where the acid value is equal to or less than 40 mg KOH/g, the polymerizable compound is advantageous in terms of production and/or handling. Moreover, a photopolymerization performance is favorable, and curing properties are excellent.

As the polymerizable compound, a compound having a caprolactone structure is also a preferred aspect.

The compound having a caprolactone structure is not particularly limited as long as the compound has a caprolactone structure in a molecule, but examples thereof include ε-caprolactone-modified polyfunctional (meth)acrylate which is obtained by esterifying polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylol melamine, (meth)acrylic acid, and ε-caprolactone. Among them, a compound which has a caprolactone structure and is represented by Formula (Z-1) is preferable.

[chemical structure]

In Formula (Z-1), all six R's are groups represented by Formula (Z-2), or one to five R's among the six R's are groups represented by Formula (Z-2) and the others are groups represented by Formula (Z-3).

[chemical structure]

In Formula (Z-2), R¹ represents a hydrogen atom or a methyl group, m represents a number of 1 or 2, and “*” represents a bond.

[chemical structure]

In Formula (Z-3), R¹ represents a hydrogen atom or a methyl group, and “*” represents a bond.

The polymerizable compound having a caprolactone structure is commercially available, for example, as KAYARAD DPCA series from Nippon Kayaku Co., Ltd., and examples thereof include DPCA-20 (a compound in which m in Formulae (Z-1) to (Z-3) is 1, the number of groups represented by Formula (Z-2) is 2, and all of R¹'s represent hydrogen atoms), DPCA-30 (a compound in which m in Formulae (Z-1) to (Z-3) is 1, the number of groups represented by Formula (Z-2) is 3, and all of R¹'s represent hydrogen atoms), DPCA-60 (a compound in which m in Formulae (Z-1) to (Z-3) is 1, the number of groups represented by Formula (Z-2) is 6, and all of R¹'s represent hydrogen atoms), and DPCA-120 (a compound in which m in Formulae (Z-1) to (Z-3) is 2, the number of groups represented by Formula (Z-2) is 6, and all of R¹'s represent hydrogen atoms). Moreover, as a commercial product of the polymerizable compound having a caprolactone structure, M-350 (trade name) (trimethylolpropane triacrylate) produced by TOAGOSEI CO., LTD. is also mentioned.

As the polymerizable compound, a compound represented by Formula (Z-4) or (Z-5) can also be used.

[chemical structure]

In Formulae (Z-4) and (Z-5), E represents —((CH₂)_{y}CH₂O)— or ((CH₂)_{y}CH(CH₃)O)—, y represents an integer of 0 to 10, and X represents a (meth)acryloyl group, a hydrogen atom, or a carboxylic acid group.

In Formula (Z-4), the total number of (meth)acryloyl groups is 3 or 4, m represents an integer of 0 to 10, and the total number of m's is an integer of 0 to 40.

In Formula (Z-5), the total number of (meth)acryloyl groups is 5 or 6, n represents an integer of 0 to 10, and the total number of n's is an integer of 0 to 60.

In Formula (Z-4), m is preferably an integer of 0 to 6 and more preferably an integer of 0 to 4.

Moreover, the total number of m's is preferably an integer of 2 to 40, more preferably an integer of 2 to 16, and even more preferably an integer of 4 to 8.

In Formula (Z-5), n is preferably an integer of 0 to 6 and more preferably an integer of 0 to 4.

Moreover, the total number of n's is preferably an integer of 3 to 60, more preferably an integer of 3 to 24, and even more preferably an integer of 6 to 12.

Furthermore, an aspect in which a terminal on the oxygen atom side of —((CH₂)_{y}CH₂O)— or ((CH₂)_{y}CH(CH₃)O)— in Formula (Z-4) or Formula (Z-5) is bonded to X is preferable.

The compounds represented by Formula (Z-4) or Formula (Z-5) may be used singly or in combination of two or more thereof. In particular, an aspect in which all of six X's in Formula (Z-5) are acryloyl groups, or a mixture of a compound in which all of six X's in Formula (Z-5) are acryloyl groups and a compound in which at least one among the six X's is a hydrogen atom is preferable. With such a configuration, the developability can be further improved.

Furthermore, the total content of the compounds represented by Formula (Z-4) or Formula (Z-5) in the polymerizable compound is preferably equal to or greater than 20% by mass and more preferably equal to or greater than 50% by mass.

Among the compounds represented by Formula (Z-4) or Formula (Z-5), a pentaerythritol derivative and/or a dipentaerythritol derivative is more preferable.

In addition, the polymerizable compound may have a cardo skeleton.

As the polymerizable compound having a cardo skeleton, a polymerizable compound having a 9,9-bisarylfluorene skeleton is preferable.

The polymerizable compound having a cardo skeleton is not limited, but examples thereof include ONCOAT EX series (produced by NAGASE & CO., LTD.), and OGSOL (produced by Osaka Gas Chemicals Co., Ltd.).

As the polymerizable compound, a compound having an isocyanuric acid skeleton as a core is also preferable. Examples of such a polymerizable compound include NK ESTER A-9300 (produced by Shin-Nakamura Chemical Co., Ltd.).

The content (which means a value obtained by dividing the number of ethylenically unsaturated groups in the polymerizable compound by the molecular weight (g/mol) of the polymerizable compound) of the ethylenically unsaturated group in the polymerizable compound is preferably equal to or greater than 5.0 mmol/g. The upper limit thereof is not particularly limited, but is generally equal to or less than 20.0 mmol/g.

[Polymerization Initiator]

The composition according to the embodiment of the present invention preferably contains a polymerization initiator.

The polymerization initiator is not particularly limited, and known polymerization initiators can be used. Examples of the polymerization initiator include a photopolymerization initiator and a thermal polymerization initiator, and a photopolymerization initiator is preferable. Moreover, as the polymerization initiator, a so-called radical polymerization initiator is preferable.

A content of the polymerization initiator in the composition is not particularly limited, but is preferably 0.5% to 20% by mass, more preferably 1.0% to 10% by mass, and even more preferably 1.5% to 8% by mass, with respect to the total solid content of the composition. The polymerization initiators may be used singly or in combination of two or more thereof. In a case where two or more polymerization initiators are used in combination, the total content thereof is preferably within the above range.

<Thermal Polymerization Initiator>

Examples of the thermal polymerization initiator include an azo compound such as 2,2′-azobisisobutyronitrile (AIBN), 3-carboxypropionitrile, azobismalononitrile, and dimethyl-(2,2′)-azobis(2-methylpropionate) [V-601] and an organic peroxide such as benzoyl peroxide, lauroyl peroxide, and potassium persulfate.

Specific examples of the polymerization initiator include the polymerization initiator described in pp. 65 to 148 of “Ultraviolet Curing System” (published by Sogo Gijutsu Center, 1989) written by Kiyomi KATO.

<Photopolymerization Initiator>

The composition preferably contains a photopolymerization initiator.

The photopolymerization initiator is not particularly limited as long as the photopolymerization initiator can initiate the polymerization of the polymerizable compound, and known photopolymerization initiators can be used. As the photopolymerization initiator, for example, a photopolymerization initiator exhibiting photosensitivity from an ultraviolet range to a visible light range is preferable. Moreover, the photopolymerization initiator may be an activator which generates active radicals by causing a certain action with a photoexcited sensitizer, or an initiator which initiates cationic polymerization according to the type of the polymerizable compound.

Furthermore, the photopolymerization initiator preferably contains at least one compound having a molar absorption coefficient of at least 50 within a range of 300 to 800 nm (more preferably 330 to 500 nm).

A content of the photopolymerization initiator in the composition is not particularly limited, but is preferably 0.5% to 20% by mass, more preferably 1.0% to 10% by mass, and even more preferably 1.5% to 8% by mass, with respect to the total solid content of the composition. The photopolymerization initiators may be used singly or in combination of two or more thereof. In a case where two or more photopolymerization initiators are used in combination, the total content thereof is preferably within the above range.

Examples of the photopolymerization initiator include a halogenated hydrocarbon derivative (for example, a compound having a triazine skeleton, a compound having an oxadiazole skeleton, or the like), an acyl phosphine compound such as acyl phosphine oxide, hexaaryl biimidazole, an oxime compound such as an oxime derivative, an organic peroxide, a thio compound, a ketone compound, an aromatic onium salt, an aminoacetophenone compound, and hydroxyacetophenone.

Regarding specific examples of the photopolymerization initiator, reference can be made to, for example, paragraphs 0265 to 0268 of JP2013-029760A, the contents of which are incorporated into the present specification.

More specifically, as the photopolymerization initiator, for example, the aminoacetophenone-based initiator described in JP1998-291969A (JP-H10-291969A) and the acyl phosphine-based initiator described in JP4225898B can also be used.

As the hydroxyacetophenone compound, for example, IRGACURE-184, DAROCUR-1173, IRGACURE-500, IRGACURE-2959, and IRGACURE-127 (trade names, all produced by BASF SE) can be used.

As the aminoacetophenone compound, for example, IRGACURE-907, IRGACURE-369, and IRGACURE-379EG (trade names, all produced by BASF SE), which are commercial products, can be used. As the aminoacetophenone compound, the compound which is described in JP2009-191179A and whose absorption wavelength is matched to a light source having a long wavelength such as a wavelength of 365 nm or a wavelength of 405 nm can also be used.

As the acyl phosphine compound, IRGACURE-819 and IRGACURE-TPO (trade names, all produced by BASF SE), which are commercial products, can be used.

(Oxime Compound)

As the photopolymerization initiator, an oxime ester-based polymerization initiator (oxime compound) is more preferable. In particular, an oxime compound has high sensitivity and high polymerization efficiency, easily designs the content of the coloring material in the composition to be high, and thus is preferable.

As specific examples of the oxime compound, the compound described in JP2001-233842A, the compound described in JP2000-080068A, or the compound described in JP2006-342166A can be used.

Examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Furthermore, the compounds described in J. C. S. Perkin II (1979) pp. 1653 to 1660, J. C. S. Perkin II (1979) pp. 156 to 162, Journal of Photopolymer Science and Technology (1995) pp. 202 to 232, JP2000-066385A, JP2000-080068A, JP2004-534797A, and JP2006-342166A is also mentioned.

Among commercial products, IRGACURE-OXE01 (produced by BASF SE), IRGACURE-OXE02 (produced by BASF SE), IRGACURE-OXE03 (produced by BASF SE), or IRGACURE-OXE04 (produced by BASF SE) is also preferable. Moreover, TR-PBG-304 (produced by TRONLY), ADEKA ARKLS NCI-831 and ADEKA ARKLS NCI-930 (produced by ADEKA CORPORATION), or N-1919 (carbazole and oxime ester skeleton-containing photoinitiator (produced by ADEKA CORPORATION)) can also be used.

In addition, as oxime compounds other than the aforementioned oxime compounds, the compound which is described in JP2009-519904A and in which oxime is linked to a N-position of carbazole; the compound which is described in U.S. Pat. No. 7,626,957B and in which a hetero substituent is introduced into a benzophenone moiety; the compounds which are described in JP2010-015025A and US2009/0292039A and in which a nitro group is introduced into the moiety of a coloring agent; the ketoxime compound described in WO2009/131189A; the compound which is described in U.S. Pat. No. 7,556,910B and contains a triazine skeleton and an oxime skeleton in the same molecule; the compound which is described in JP2009-221114A, has absorption maximum at 405 nm, and exhibits favorable sensitivity with respect to a light source of a g-line; and the like may be used.

Reference can be made to, for example, paragraphs 0274 and 0275 of JP2013-029760A, the contents of which are incorporated into the present specification.

Specifically, as the oxime compound, a compound represented by Formula (OX-1) is preferable. Moreover, a N—O bond in the oxime compound may be an (E) isomer, a (Z) isomer, or a mixture of an (E) isomer and a (Z) isomer.

[chemical structure]

In Formula (OX-1), R and B each independently represent a monovalent substituent, A represents a divalent organic group, and Ar represents an aryl group.

In Formula (OX-1), the monovalent substituent represented by R is preferably a group of monovalent nonmetallic atoms.

Examples of the group of monovalent nonmetallic atoms include an alkyl group, an aryl group, an acyl group, an alkoxycarbonyl group, an aryloxycarbonyl group, a heterocyclic group, an alkylthiocarbonyl group, and an arylthiocarbonyl group. Moreover, these groups may have one or more substituents. Furthermore, each of the substituents may be further substituted with another substituent.

Examples of the substituent include a halogen atom, an aryloxy group, an alkoxycarbonyl group or an aryloxycarbonyl group, an acyloxy group, an acyl group, an alkyl group, and an aryl group.

As the monovalent substituent represented by B in Formula (OX-1), an aryl group, a heterocyclic group, an arylcarbonyl group, or a heterocyclic carbonyl group is preferable, and an aryl group or a heterocyclic group is more preferable. These groups may have one or more substituents. Examples of the substituents include the aforementioned substituents.

As the divalent organic group represented by A in Formula (OX-1), an alkylene group having 1 to 12 carbon atoms, a cycloalkylene group, or an alkynylene group is preferable. These groups may have one or more substituents. Examples of the substituents include the aforementioned substituents.

As the photopolymerization initiator, a fluorine atom-containing oxime compound can also be used. Specific examples of the fluorine atom-containing oxime compound include the compound described in JP2010-262028A; the compounds 24 and 36 to 40 described in JP2014-500852A; and the compound (C-3) described in JP2013-164471A. The contents thereof are incorporated into the present specification.

As the photopolymerization initiator, compounds represented by Formulae (1) to (4) can also be used.

[chemical structure]

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, in a case where R¹ and R² each represent a phenyl group, the phenyl groups may be bonded to each other to form a fluorene group, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (2), R¹, R², R³, and R⁴ have the same definitions as R¹, R², R³, and R⁴ in

Formula (1), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formula (3), R¹ represents an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (4), R′, R³, and R⁴ have the same definitions as R′, R³, and R⁴ in Formula (3), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formulae (1) and (2), R¹ and R² are each preferably a methyl group, an ethyl group, an n-propyl group, an i-propyl group, a cyclohexyl group, or a phenyl group. R³ is preferably a methyl group, an ethyl group, a phenyl group, a tolyl group, or a xylyl group. R⁴ is preferably an alkyl group having 1 to 6 carbon atoms or a phenyl group. R⁵ is preferably a methyl group, an ethyl group, a phenyl group, a tolyl group, or a naphthyl group. X is preferably a direct bond.

Furthermore, in Formulae (3) and (4), R¹ is preferably a methyl group, an ethyl group, an n-propyl group, an i-propyl group, a cyclohexyl group, or a phenyl group. R³ is preferably a methyl group, an ethyl group, a phenyl group, a tolyl group, or a xylyl group. R⁴ is preferably an alkyl group having 1 to 6 carbon atoms or a phenyl group. R⁵ is preferably a methyl group, an ethyl group, a phenyl group, a tolyl group, or a naphthyl group. X is preferably a direct bond.

Specific examples of the compounds represented by Formula (1) and Formula (2) include the compound described in paragraphs 0076 to 0079 of JP2014-137466A. The contents thereof are incorporated into the present specification.

Specific examples of an oxime compound preferably used in the composition are shown below. Among the oxime compounds shown below, an oxime compound represented by General Formula (C-13) is more preferable.

Furthermore, as the oxime compound, the compounds described in Table 1 of WO2015/036910A can also be used, the contents of which are incorporated into the present specification.

[chemical structure]

[chemical structure]

[chemical structure]

The oxime compound preferably has a maximum absorption wavelength in a wavelength range of 350 to 500 nm, more preferably has a maximum absorption wavelength in a wavelength range of 360 to 480 nm, and even more preferably has a high absorbance at wavelengths of 365 nm and 405 nm.

From the viewpoint of sensitivity, a molar absorption coefficient of the oxime compound at 365 nm or 405 nm is preferably 1,000 to 300,000, more preferably 2,000 to 300,000, and even more preferably 5,000 to 200,000.

The molar absorption coefficient of the compound can be measured by known methods, but for example, it is preferable that the measurement is carried out with an ultraviolet and visible spectrophotometer (Cary-5 spectrophotometer manufactured by Varian, Inc.) at a concentration of 0.01 g/L using ethyl acetate.

If necessary, two or more photopolymerization initiators may be used in combination.

In addition, as the photopolymerization initiator, the compounds described in paragraph 0052 of JP2008-260927A, paragraphs 0033 to 0037 of JP2010-097210A, and paragraph 0044 of JP2015-068893A can also be used, the contents of which are incorporated into the present specification.

[Polymerization Inhibitor]

The composition may contain a polymerization inhibitor.

The polymerization inhibitor is not particularly limited, and known polymerization inhibitors can be used. Examples of the polymerization inhibitor include a phenolic polymerization inhibitor (for example, p-methoxyphenol, 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthol, and the like); a hydroquinone-based polymerization inhibitor (for example, hydroquinone, 2,6-di-tert-butylhydroquinone, and the like); a quinone-based polymerization inhibitor (for example, benzoquinone and the like); a free radical-based polymerization inhibitor (for example, 2,2,6,6-tetramethylpiperidine 1-oxyl free radical, 4-hydroxy-2,2,6,6-tetramethylpiperidine 1-oxyl free radicals, and the like); a nitrobenzene-based polymerization inhibitor (for example, nitrobenzene, 4-nitrotoluene, and the like); and a phenothiazine-based polymerization inhibitor (for example, phenothiazine, 2-methoxyphenothiazine, and the like).

Among them, from the viewpoint that the composition has a superior effect, a phenolic polymerization inhibitor or a free radical-based polymerization inhibitor is preferable.

In a case where the polymerization inhibitor is used together with a resin containing a curable group, the effect thereof is remarkable.

A content of the polymerization inhibitor in the composition is not particularly limited, but is preferably 0.0001% to 0.5% by mass, more preferably 0.001% to 0.2% by mass, and even more preferably 0.008% to 0.05% by mass, with respect to the total solid content of the composition. The polymerization inhibitors may be used singly or in combination of two or more thereof. In a case where two or more polymerization inhibitors are used in combination, the total content thereof is preferably within the above range.

Furthermore, a ratio (content of polymerization inhibitor/content of polymerizable compound (mass ratio)) of the content of the polymerization inhibitor to the content of the polymerizable compound in the composition is preferably greater than 0.0005, more preferably 0.0006 to 0.02, and even more preferably 0.0006 to 0.005.

[Ultraviolet Absorber]

The composition may contain an ultraviolet absorber. By doing so, a pattern shape of a cured film can be made into a superior (fine) shape.

As the ultraviolet absorber, salicylate-based, benzophenone-based, benzotriazole-based, substituted acrylonitrile-based, and triazine-based ultraviolet absorbers can be used. As specific examples thereof, the compound described in paragraphs 0137 to 0142 of JP2012-068418A (corresponding to paragraphs 0251 to 0254 of US2012/0068292A) can be used, the contents of which can be incorporated by reference into the present specification.

In addition to the aforementioned compounds, a diethylamino-phenylsulfonyl-based ultraviolet absorber (produced by DAITO CHEMICAL CO., LTD., trade name, UV-503) or the like is also suitably used.

Examples of the ultraviolet absorber include the compounds exemplified in paragraphs 0134 to 0148 of JP2012-032556A.

A content of the ultraviolet absorber is preferably 0.001% to 15% by mass, more preferably 0.01% to 10% by mass, and even more preferably 0.1% to 5% by mass, with respect to the total solid content of the composition.

[Silane Coupling Agent (Adhesive Agent)]

The composition may contain a silane coupling agent. The silane coupling agent functions as an adhesive agent which improves adhesiveness between a substrate and a cured film in a case where the cured film is formed on the substrate.

The silane coupling agent is a compound containing a hydrolyzable group and other functional groups in a molecule. Moreover, the hydrolyzable group such as an alkoxy group is bonded to the silicon atom.

The hydrolyzable group refers to a substituent which is directly bonded to a silicon atom and can form a siloxane bond by a hydrolysis reaction and/or a condensation reaction. Examples of the hydrolyzable group include a halogen atom, an alkoxy group, an acyloxy group, and an alkenyloxy group. In a case where the hydrolyzable group contains a carbon atom, the number of carbon atoms is preferably equal to or smaller than 6 and more preferably equal to or smaller than 4. In particular, an alkoxy group having 4 or less carbon atoms or an alkenyloxy group having 4 or less carbon atoms is preferable.

Furthermore, in a case where a cured film is formed on a substrate, in order to improve adhesiveness between the substrate and the cured film, the silane coupling agent preferably does not contain a fluorine atom and a silicon atom (here, a silicon atom to which a hydrolyzable group is bonded is excluded), and desirably does not contain a fluorine atom, a silicon atom (here, a silicon atom to which a hydrolyzable group is bonded is excluded), an alkylene group substituted with a silicon atom, a linear alkyl group having 8 or more carbon atoms, and a branched alkyl group having 3 or more carbon atoms.

The silane coupling agent may contain an ethylenically unsaturated group such as a (meth)acryloyl group. In a case where the silane coupling agent contains an ethylenically unsaturated group, the number thereof is preferably 1 to 10 and more preferably 4 to 8. Moreover, the silane coupling agent (for example, a compound which contains a hydrolyzable group and an ethylenically unsaturated group and has a molecular weight equal to or less than 2,000) containing an ethylenically unsaturated group does not correspond to the aforementioned polymerizable compound.

A content of the silane coupling agent in the composition is preferably 0.1% to 10% by mass, more preferably 0.5% to 8% by mass, and even more preferably 1.0% to 6% by mass, with respect to the total solid content in the composition.

The composition may contain one silane coupling agent singly or two or more silane coupling agents. In a case where the composition contains two or more silane coupling agents, the total amount thereof may be within the above range.

Examples of the silane coupling agent include 3-glycidoxypropyl trimethoxysilane, 3-glycidoxypropyl triethoxysilane, 3-glycidoxypropyl methyldimethoxysilane, 3-glycidoxypropyl methyldiethoxysilane, vinyltrimethoxysilane, and vinyltriethoxysilane.

[Surfactant]

The composition may contain a surfactant. The surfactant contributes to improvement in coating properties of the composition.

In a case where the composition contains a surfactant, a content of the surfactant is preferably 0.001% to 2.0% by mass, more preferably 0.005% to 0.5% by mass, and even more preferably 0.01% to 0.1% by mass, with respect to the total solid content of the composition.

The surfactants may be used singly or in combination of two or more thereof. In a case where two or more surfactants are used in combination, the total amount thereof is preferably within the above range.

Examples of the surfactant include a fluorine-based surfactant, a nonionic surfactant, a cationic surfactant, an anionic surfactant, and a silicone-based surfactant.

For example, in a case where the composition contains a fluorine-based surfactant, liquid characteristics (particularly, fluidity) of the composition are further improved. That is, in a case where a film is formed of the composition containing the fluorine-based surfactant, an interfacial tension between a surface to be coated and a coating liquid is reduced, and accordingly, wettability with respect to the surface to be coated is improved, and coating properties to the surface to be coated are improved. Therefore, even in a case where a thin film having a thickness of about several micrometers is formed with a small amount of a liquid, the fluorine-based surfactant is effective from the viewpoint that a film having a uniform thickness and small thickness unevenness is more suitably formed.

A content ratio of fluorine in the fluorine-based surfactant is preferably 3% to 40% by mass, more preferably 5% to 30% by mass, and even more preferably 7% to 25% by mass. A fluorine-based surfactant having a content ratio of fluorine within the above range is effective from the viewpoint of uniformity of the thickness of the coating film and/or liquid saving properties, and also has favorable solubility in the composition.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, and MEGAFACE F780 (all produced by DIC Corporation); FLUORAD FC430, FLUORAD FC431, and FLUORAD FC171 (all produced by Sumitomo 3M Limited); SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all produced by ASAHI GLASS CO., LTD.); and PF636, PF656, PF6320, PF6520, and PF7002 (produced by OMNOVA Solutions Inc.).

As the fluorine-based surfactant, a block polymer can also be used, and specific examples thereof include the compound described in JP2011-089090A.

[Solvent]

The composition preferably contains a solvent.

The solvent is not particularly limited, and known solvents can be used.

A content of the solvent in the composition is not particularly limited, but is preferably an amount such that the solid content of the composition is 10% to 90% by mass, more preferably an amount such that the solid content of the composition is 10% to 40% by mass, and even more preferably an amount such that the solid content of the composition is 15% to 35% by mass.

The solvents may be used singly or in combination of two or more thereof. In a case where two or more solvents are used in combination, the content thereof is preferably adjusted so that the total solid content of the composition is within the above range.

Examples of the solvent include water and an organic solvent.

<Organic Solvent>

Examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetyl acetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxy ethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, y-butyrolactone, butyl acetate, methyl lactate, N-methyl-2-pyrrolidone, and ethyl lactate, but the present invention is not limited to these examples.

<Water>

In a case where the composition contains water, a content thereof is preferably 0.001% to 5.0% by mass, more preferably 0.01% to 3.0% by mass, and even more preferably 0.1% to 1.0% by mass, with respect to the total mass of the composition.

In particular, in a case where the content of the water is equal to or less than 3.0% by mass (more preferably equal to or less than 1.0% by mass) with respect to the total mass of the composition, deterioration of the viscosity stability over time due to hydrolysis or the like of the components in the composition is easily suppressed, and in a case where the content is equal to or greater than 0.01% by mass (preferably equal to or greater than 0.1% by mass), precipitation stability over time is easily improved.

[Other Optional Components]

The composition may further contain optional components other than the aforementioned components. Examples thereof include a sensitizer, a co-sensitizer, a crosslinking agent, a curing accelerator, a heat curing accelerator, a plasticizer, a diluent, and an oil sensitizer, and known additives such as an adhesion promoter to the surface of the substrate and other auxiliaries (for example, conductive particles, a filling agent, an anti-foaming agent, a flame retardant, a leveling agent, a peeling accelerator, an antioxidant, a fragrance, a surface tension adjuster, a chain transfer agent, and the like) may be added, if necessary.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the specification of the present application.

[Method for Producing Light-Shielding Composition]

The composition is preferably obtained by first producing a coloring material composition containing a black coloring material, and further mixing the obtained coloring material composition with other components.

The coloring material composition is preferably prepared by mixing a black coloring material, a resin (preferably, a dispersant), and a solvent. Moreover, it is also preferable that a polymerization inhibitor is incorporated into the coloring material composition.

The coloring material composition can be prepared by mixing the aforementioned respective components by known mixing methods (for example, mixing methods using a stirrer, a homogenizer, a high-pressure emulsification device, a wet-type pulverizer, a wet-type disperser, or the like).

In a case of preparing the light-shielding composition, the respective components may be formulated at once, or each of the components may be dissolved or dispersed in a solvent and then sequentially formulated. Moreover, the input order and the operation conditions during the formulation are not particularly limited.

For the purpose of removing foreign substances, reducing defects, and the like, the light-shielding composition is preferably filtered with a filter. The filter can be used without particular limitation as long as the filter has been used in the related art in a filtration application or the like. Examples of the filter include filters made of a fluorine resin such as polytetrafluoroethylene (PTFE), a polyamide-based resin such as nylon, a polyolefin-based resin (having a high density and an ultrahigh molecular weight) such as polyethylene and polypropylene (PP), or the like. Among these materials, polypropylene (including high-density polypropylene) and nylon are preferable.

A pore size of the filter is preferably 0.1 to 7.0 more preferably 0.2 to 2.5 even more preferably 0.2 to 1.5 and particularly preferably 0.3 to 0.7 In a case where the pore size is within the above range, it is possible to reliably remove fine foreign substances, such as impurities and aggregates, contained in a pigment while suppressing filtration clogging of the pigment (including a black pigment).

In a case of using a filter, different filters may be combined. In this case, filtering with a first filter may be performed only once, or may be performed twice or more times. In a case where filtering is performed twice or more times with a combination of different filters, the pore sizes of the filters used in the second and subsequent filtering are preferably the same as or larger than the pore size of the filter used in the first filtering. Moreover, the first filters having different pore sizes within the above range may be combined. Regarding the pore size mentioned here, reference can be made to nominal values of filter manufacturers. A commercial filter can be selected from, for example, various filters provided by Nihon Pall Ltd., Advantec Toyo Kaisha, Ltd., Nihon Entegris K. K. (formerly Nippon Microlith Co., Ltd.), Kitz Micro Filter Corporation, and the like.

As a second filter, a filter formed of the same material as that of the first filter, or the like can be used. A pore size of the second filter is preferably 0.2 to 10.0 μm, more preferably 0.2 to 7.0 μm, and even more preferably 0.3 to 6.0 μm.

The composition preferably does not contain impurities such as a metal, a halogen-containing metal salt, an acid, and an alkali. A content of impurities contained in these materials is preferably equal to or less than 1 ppm by mass, more preferably equal to or less than 1 ppb by mass, even more preferably equal to or less than 100 ppt by mass, and particularly preferably equal to or less than 10 ppt by mass, and it is most preferable that the impurities are substantially not contained (the content is equal to or less than the detection limit of the measuring device).

Furthermore, the impurities can be measured using an inductively coupled plasma mass spectrometer (manufactured by Agilent Technologies, Inc., Agilent 7500cs model).

[Manufacturing of Cured Film]

A composition layer formed of the light-shielding composition according to the embodiment of the present invention is cured to obtain a cured film (including a pattern-like cured film).

The method for manufacturing a cured film is not particularly limited, but preferably includes the following steps.
Composition layer forming step
Exposure step
Development step Hereinafter, each of the steps will be described.

[Composition Layer Forming Step]

In the composition layer forming step, prior to exposure, the composition is applied on a support or the like to form a layer (composition layer) of the composition. As the support, for example, a substrate for a solid-state imaging element, in which an imaging element (light-receiving element) such as a charge coupled device (CCD) and a complementary metal-oxide semiconductor (CMOS) is provided on a substrate (for example, a silicon substrate), can be used. Moreover, in order to improve adhesion with the upper layer, prevent the diffusion of substances, and planarize the surface of the substrate, an undercoat layer may be provided on the support, if necessary.

As a method for applying the composition onto the support, various coating methods such as a slit coating method, an ink jet method, a spin coating method, a cast coating method, a roll coating method, and a screen printing method can be applied. The film thickness of the composition layer is preferably 0.1 to 10 μm, more preferably 0.2 to 5 μm, and even more preferably 0.2 to 3 μm. The composition layer applied on the support can be dried (pre-baked) at a temperature of 50° C. to 140° C. for 10 to 300 seconds, for example, using a hot plate, an oven, or the like.

[Exposure Step]

In the exposure step, the composition layer formed in the composition layer forming step is exposed by irradiation with actinic rays or radiation, and the composition layer irradiated with light is cured.

The method of light irradiation is not particularly limited, but light irradiation is preferably performed through a photo mask having a pattern-like opening part.

The exposure is preferably performed by irradiation with radiation. Ultraviolet rays such as a g-line, an h-line, and an i-line are particularly preferable as the radiation which can be used during the exposure, and a high-pressure mercury lamp is preferable as a light source. The irradiation intensity is preferably 5 to 1,500 mJ/cm² and more preferably 10 to 1,000 mJ/cm².

In addition, in a case where the composition contains a thermal polymerization initiator, the composition layer may be heated in the exposure step. A heating temperature is not particularly limited, but is preferably 80° C. to 250° C. A heating time is not particularly limited, but is preferably 30 to 300 seconds.

Furthermore, in a case where the composition layer is heated in the exposure step, the exposure step may serve as a post-heating step which will be described later. In other words, in a case where the composition layer is heated in the exposure step, the method for manufacturing a cured film may not include the post-heating step.

[Development Step]

The development step is a step of developing the exposed composition layer to form a cured film. By this step, the composition layer in a portion which is not irradiated in the exposure step is eluted, only a photo-cured portion remains, and thus a pattern-like cured film can be obtained.

A type of a developer used in the development step is not particularly limited, but an alkaline developer which does not damage the underlying imaging element and circuit or the like is desirable.

The development temperature is 20° C. to 30° C., for example.

The development time is 20 to 90 seconds, for example. In order to further efficiently remove the residues, in recent years, the development may be performed for 120 to 180 seconds. Furthermore, in order to further improve residue removability, a step of shaking off the developer every 60 seconds and further supplying a fresh developer may be repeated several times.

The alkaline developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dim ethyl ethanol amine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, organic alkalis are preferable).

Furthermore, in a case where the alkaline compound is used as an alkaline developer, the alkaline compound is generally subjected to a washing treatment with water after development.

[Post-Baking]

A heating treatment (post-baking) is preferably performed after the exposure step. The post-baking is a heating treatment after development in order to complete the curing. The heating temperature is preferably equal to or lower than 240° C. and more preferably equal to or lower than 220° C. The lower limit thereof is not particularly limited, but is preferably equal to or higher than 50° C. and more preferably equal to or higher than 100° C., in consideration of an efficient and effective treatment.

The post-baking can be performed continuously or batchwise by using a heating unit such as a hot plate, a convection oven (hot-air circulating dryer), and a radio-frequency heater.

The post-baking is preferably performed in an atmosphere of a low oxygen concentration. The oxygen concentration is preferably equal to or lower than 19% by volume, more preferably equal to or lower than 15% by volume, even more preferably equal to or lower than 10% by volume, particularly preferably equal to or lower than 7% by volume, and most preferably equal to or lower than 3% by volume. The lower limit thereof is not particularly limited, but is practically equal to or higher than 10 ppm by volume.

In addition, the curing may be completed by irradiation with ultraviolet rays (UV) instead of the post-baking by heating.

In this case, it is preferable that the composition further contains a UV curing agent. The UV curing agent is preferably a UV curing agent which can be cured at a wavelength shorter than 365 nm that is an exposure wavelength of a polymerization initiator added for a lithography step by ordinary i-line exposure. Examples of the UV curing agent include CIBA IRGACURE 2959 (trade name). In a case where UV irradiation is performed, the composition layer is preferably a material which is cured at a wavelength equal to or less than a wavelength of 340 nm. The lower limit value of the wavelength is not particularly limited, but is generally equal to or greater than 220 nm. Moreover, an exposure amount of the UV irradiation is preferably 100 to 5,000 mJ, more preferably 300 to 4,000 mJ, and even more preferably 800 to 3,500 mJ. The UV curing step is preferably performed after the exposure step because low-temperature curing is more effectively performed. As an exposure light source, an ozoneless mercury lamp is preferably used.

[Physical Properties of Cured Film and Application of Cured Film]

[Physical Properties of Cured Film]

From the viewpoint that excellent light-shielding properties are exhibited, in a cured film formed of the light-shielding composition according to the embodiment of the present invention, an optical density (OD) per film thickness of 1.0 μm in a wavelength range of 400 to 1,200 nm is preferably equal to or higher than 1.7, more preferably equal to or higher than 2.0, and even more preferably equal to or higher than 2.1. Moreover, the upper limit value thereof is not particularly limited, but is preferably equal to or lower than 10, in general. The cured film can be preferably used as a light-shielding film.

In the present specification, the expression that the optical density per film thickness of 1.0 μm in a wavelength range of 400 to 1,200 nm is equal to or higher than 2.0 means that an optical density per film thickness of 1.0 μm in the entire wavelength range of 400 to 1,200 nm is equal to or higher than 2.0.

Moreover, in the present specification, as a method for measuring the optical density of the cured film, a cured film is first formed on a glass substrate, measurement using an integrating sphere-type light-receiving unit of a spectrophotometer U-4100 (trade name, manufactured by Hitachi High-Technologies Corporation) is performed, the film thickness at a measurement location is also measured, and an optical density per predetermined film thickness is calculated.

The film thickness of the cured film is preferably 0.1 to 4.0 μm and more preferably 1.0 to 2.5 μm, for example. The cured film may be thinner or thicker than the above range depending on the application.

Furthermore, in a case where the cured film is used as a light-attenuating film, the light-shielding properties may be adjusted by making the cured film thinner (for example, 0.1 to 0.5 μm) than the above range. In this case, the optical density per film thickness of 1.0 μm in a wavelength range of 400 to 1,200 nm is preferably 0.1 to 1.5 and more preferably 0.2 to 1.0.

The reflectivity of the cured film is preferably less than 5%, more preferably less than 3%, and even more preferably less than 1%.

In addition, the cured film is suitable for a light-shielding member, a light-shielding film, an antireflection member, and an antireflection film of optical filters and modules which are used in portable instruments such as a personal computer, a tablet PC, a mobile phone, a smartphone, and a digital camera; office automation (OA) instruments such as a printer composite machine and a scanner; industrial instruments such as monitoring camera, a barcode reader, an automated teller machine (ATM), a high-speed camera, and an instrument having a personal authentication function using face image authentication or biometric authentication; in-vehicle camera instruments; medical camera instruments such as an endoscope, a capsule endoscope, and a catheter; a biosensor, a military reconnaissance camera, a camera for a three-dimensional map, a camera for observing weather and sea, a camera for a land resource exploration, and space instruments such as an exploration camera for the astronomy of the space and a deep space target; and the like.

The cured film can also be used in applications of a micro light emitting diode (LED), a micro organic light emitting diode (OLED), and the like. The cured film is suitable for an optical filter and an optical film used in the micro LED and the micro OLED as well as a member which imparts a light-shielding function or an antireflection function.

Examples of the micro LED and the micro OLED include the examples described in JP2015-500562A and JP2014-533890A.

The cured film is also suitable as an optical filter and an optical film used in a quantum dot sensor and a quantum dot solid-state imaging element. Moreover, the cured film is suitable as a member which imparts a light-shielding function or an antireflection function. Examples of the quantum dot sensor and the quantum dot solid-state imaging element include the examples described in US2012/0037789A and WO2008/131313A.

[Light-Shielding Film, Optical Element, Solid-State Imaging Element, and Solid-State Imaging Device]

It is also preferable that the cured film according to the embodiment of the present invention is used as a so-called light-shielding film. It is also preferable that such a light-shielding film is used in a solid-state imaging element.

As described above, the cured film formed of the light-shielding composition according to the embodiment of the present invention has excellent light-shielding properties, low-reflection properties, and in-plane uniformity of a reflectivity.

Moreover, the cured film formed of the composition according to the embodiment of the present invention has excellent light resistance and excellent moisture resistance by forming the layer, in which the specific particles are present in a high concentration, on the surface side of the cured film.

Furthermore, the light-shielding film is one of the preferable applications in the cured film according to the embodiment of the present invention, and the light-shielding film according to the embodiment of the present invention can be manufactured in the same manner as the method for manufacturing a cured film. Specifically, a light-shielding film can be manufactured by applying the composition to a substrate to form a composition layer, and performing exposure and development on the composition layer.

The present invention also includes an invention of an optical element. The optical element according to the embodiment of the present invention is an optical element including the aforementioned cured film (light-shielding film). Examples of the optical element include optical elements used in optical equipment such as a camera, binoculars, a microscope, and a semiconductor exposure device.

Among them, as the optical element, for example, a solid-state imaging element mounted on a camera or the like is preferable.

In addition, the solid-state imaging element according to the embodiment of the present invention is a solid-state imaging element including the cured film (light-shielding film) according to the embodiment of the present invention.

An aspect in which the solid-state imaging element according to the embodiment of the present invention includes the cured film (light-shielding film) is not particularly limited, and examples thereof include an aspect in which a plurality of photodiodes and light-receiving elements consisting of polysilicon or the like, which constitute a light-receiving area of a solid-state imaging element (a CCD image sensor, a CMOS image sensor, or the like), are provided on a substrate, and solid-state imaging element includes the cured film on a surface side (for example, a portion other than light receiving sections and/or pixels for adjusting color) of a support on which the light-receiving elements are formed or on a side opposite to the surface on which the light-receiving elements are formed.

Moreover, in a case where the cured film is used as a light-attenuating film, for example, by disposing the light-attenuating film so that a part of light passes through the light-attenuating film and then is incident on a light-receiving element, the dynamic range of the solid-state imaging element can be improved.

The solid-state imaging device is equipped with the aforementioned solid-state imaging element.

Examples of the constitutions of the solid-state imaging device and the solid-state imaging element will be described with reference to FIGS. 1 and 2. In FIGS. 1 and 2, in order that each part is clearly seen, some parts are magnified in disregard of a thickness ratio and/or a width ratio between the parts.

FIG. 1 is a schematic cross-sectional view showing an example of the constitution of the solid-state imaging device including the solid-state imaging element according to the embodiment of the present invention.

As shown in FIG. 1, a solid-state imaging device 100 comprises a rectangular solid-state imaging element 101 and a transparent cover glass 103 which is held above the solid-state imaging element 101 and seals the solid-state imaging element 101. Moreover, on the cover glass 103, a lens layer 111 is superposably provided through a spacer 104. The lens layer 111 includes a support 113 and a lens material 112. The lens layer 111 may have a constitution in which the support 113 and the lens material 112 are integrally formed. In a case where stray light is incident on the peripheral edge region of the lens layer 111, due to the diffusion of light, an effect of light condensation on the lens material 112 is weakened, and thus the light reaching an imaging part 102 is reduced. Moreover, noise is also generated due to the stray light. Therefore, a light-shielding film 114 is provided in the peripheral edge region of the lens layer 111 so that light is shielded. The cured film according to the embodiment of the present invention can also be used as the light-shielding film 114.

The solid-state imaging element 101 performs photoelectric conversion on an optical image formed on the imaging part 102 serving as a light-receiving surface of the solid-state imaging element 101, and outputs the converted optical image as an image signal. The solid-state imaging element 101 comprises a laminated substrate 105 obtained by laminating two sheets of substrates. The laminated substrate 105 consists of a chip substrate 106 and a circuit substrate 107 which have the same size and a rectangular shape, and the circuit substrate 107 is laminated on the rear surface of the chip substrate 106.

A material of the substrate used as the chip substrate 106 is not particularly limited, and known materials can be used.

The imaging part 102 is provided in the central part of the surface of the chip substrate 106. Moreover, a light-shielding film 115 is provided in the peripheral edge region of the imaging part 102. By shielding stray light incident on the peripheral edge region by the light-shielding film 115, the generation of a dark current (noise) from a circuit in the peripheral edge region can be prevented. The cured film according to the embodiment of the present invention is preferably used as the light-shielding film 115.

A plurality of electrode pads 108 are provided at an edge part of the surface of the chip substrate 106. The electrode pads 108 are electrically connected to the imaging part 102 through a signal wire (a bonding wire can also be used) (not shown) provided on the surface of the chip substrate 106.

On the rear surface of the circuit substrate 107, external connection terminals 109 are provided at positions approximately below the electrode pads 108, respectively. The external connection terminals 109 are respectively connected to the electrode pads 108 through a through electrode 110 vertically passing through the laminated substrate 105. Moreover, the external connection terminals 109 are connected to a control circuit controlling the driving of the solid-state imaging element 101, an image processing circuit performing image processing on an imaging signal output from the solid-state imaging element 101, and the like through wiring (not shown).

FIG. 2 shows a schematic cross-sectional view of the imaging part 102. As shown in FIG. 2, the imaging part 102 includes the parts, such as a light-receiving element 201, a color filter 202, and a microlens 203, provided on a substrate 204. The color filter 202 has a blue pixel 205b, a red pixel 205r, a green pixel 205g, and a black matrix 205bm. The cured film according to the embodiment of the present invention may be used as the black matrix 205bm.

As the material of the substrate 204, the same material as that of the chip substrate 106 can be used. On the surface layer of the substrate 204, a p-well layer 206 is formed. In the p-well layer 206, the light-receiving elements 201, which consist of an n-type layer and generate and accumulate signal charges by photoelectric conversion, are formed to be arranged in the form of square grids.

On one lateral side of each light-receiving element 201, through a reading gate part 207 on the surface layer of the p-well layer 206, a vertical electric charge transfer path 208 consisting of an n-type layer is formed. Moreover, on the other lateral side of each light-receiving element 201, through an element separation region 209 consisting of a p-type layer, a vertical electric charge transfer path 208 belonging to the adjacent pixel is formed. The reading gate part 207 is a channel region for the signal charges accumulated in the light-receiving element 201 to be read out toward the vertical electric charge transfer path 208.

On the surface of the substrate 204, a gate insulating film 210 consisting of an oxide-nitride-oxide (ONO) film is formed. On the gate insulating film 210, vertical electric charge transfer electrodes 211 consisting of polysilicon or amorphous silicon are formed to cover the portions which are approximately immediately above the vertical electric charge transfer path 208, the reading gate part 207, and the element separation region 209. The vertical electric charge transfer electrodes 211 function as driving electrodes for driving the vertical electric charge transfer path 208 and performing charge transfer, and as reading electrodes for driving the reading gate part 207 and reading out signal charges. The signal charges are transferred to a horizontal electric charge transfer path and an output part (floating diffusion amplifier), which are not shown in the drawing, in this order from the vertical electric charge transfer path 208, and then output as voltage signals.

On each of the vertical electric charge transfer electrodes 211, a light-shielding film 212 is formed to cover the surface of the electrode. The light-shielding film 212 has an opening part at a position immediately above the light-receiving element 201 and shields a region other than the opening part from light. The cured film according to the embodiment of the present invention may be used as the light-shielding film 212.

On the light-shielding film 212, a transparent interlayer which consists of an insulating film 213 consisting of borophosphosilicate glass (BPSG), an insulating film (passivation film) 214 consisting of P-SiN, and a planarization film 215 consisting of a transparent resin or the like is provided. The color filter 202 is formed on the interlayer.

[Image Display Device]

An image display device of the present invention is equipped with the cured film according to the embodiment of the present invention.

Examples of the aspect in which the image display device includes a cured film include an aspect in which a cured film is contained in a black matrix and a color filter including such a black matrix is used in an image display device.

Next, a black matrix and a color filter including the black matrix will be described, and a liquid crystal display device including such a color filter will be described as a specific example of the image display device.

<Black Matrix>

It is also preferable that the cured film according to the embodiment of the present invention is included in the black matrix. The black matrix is incorporated into a color filter, a solid-state imaging element, and an image display device such as a liquid crystal display device in some cases.

Examples of the black matrix include those described above; a black rim provided in the peripheral edge part of an image display device such as a liquid crystal display device; a lattice-like and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast and to prevent image quality deterioration resulting from current leakage of light in a case of an active matrix driving-type liquid crystal display device using a thin film transistor (TFT), the black matrix preferably has high light-shielding properties (the optical density OD is equal to or higher than 3).

The method for manufacturing the black matrix is not particularly limited, but the black matrix can be manufactured in the same manner as the method for manufacturing the cured film. Specifically, by applying the composition on a substrate to form a composition layer and performing exposure and development on the composition layer, a pattern-like cured film (black matrix) can be manufactured. Moreover, the film thickness of the cured film used as the black matrix is preferably 0.1 to 4.0 μm.

The material of the substrate is not particularly limited, but preferably has a transmittance equal to or greater than 80% for visible light (wavelength of 400 to 800 nm). Specific examples of such a material include glass such as soda lime glass, alkali-free glass, quartz glass, and borosilicate glass; and plastic such as a polyester-based resin and a polyolefin-based resin, and from the viewpoints of chemical resistance and heat resistance, alkali-free glass, quartz glass, or the like is preferable.

<Color Filter>

It is also preferable that the cured film according to the embodiment of the present invention is included in a color filter.

The aspect in which the color filter includes the cured film is not particularly limited, but examples thereof include a color filter comprising a substrate and the aforementioned black matrix. That is, examples thereof include a color filter comprising colored pixels of red, green, and blue which are formed in the opening part of the black matrix formed on a substrate.

The color filter including a black matrix (cured film) can be manufactured, for example, by the following method.

First, in an opening part of a pattern-like black matrix formed on a substrate, a coating film (composition layer) of a composition containing pigments corresponding to the respective colored pixels of the color filter is formed. Moreover, the composition for each color is not particularly limited, known compositions can be used, but in the composition described in the present specification, it is preferable that a composition in which the black coloring material is replaced with a colorant corresponding to each pixel is used.

Subsequently, the composition layer is subjected to exposure through a photo mask having a pattern corresponding to the opening part of the black matrix. Next, colored pixels can be formed in the opening part of the black matrix by removing an unexposed portion by a development treatment, and then performing baking. In a case where the series of operations are performed using, for example, a composition for each color containing red, green, and blue pigments, a color filter having red, green, and blue pixels can be manufactured.

<Liquid Crystal Display Device>

It is also preferable that the cured film according to the embodiment of the present invention is included in a liquid crystal display device. The aspect in which the liquid crystal display device includes the cured film is not particularly limited, but examples thereof include an aspect in which a liquid crystal display device includes the color filter including the black matrix (cured film) described above.

Examples of the liquid crystal display device according to the present embodiment include an aspect in which a liquid crystal display device comprises a pair of substrates disposed to face each other and a liquid crystal compound sealed into the space between the substrates. The substrates are as described above as the substrate for a black matrix.

Examples of a specific aspect of the liquid crystal display device include a laminate having polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, the liquid crystal display device is not limited to the aforementioned liquid crystal display devices, and examples thereof include the liquid crystal display devices described in “Electronic display device (written by Akio SASAKI, Kogyo Chosakai Publishing Co., Ltd., published in 1990)”, “Display device (written by Sumiaki IBUKI, Sangyo Tosho Publishing Co., Ltd., published in 1989)”, or the like. Moreover, examples thereof include the liquid crystal display device described in “Next-Generation Liquid Crystal Display Technology (edited by Tatsuo UCHIDA, Kogyo Chosakai Publishing Co., Ltd., published in 1994)”.

[Infrared Sensor]

It is also preferable that the cured film according to the embodiment of the present invention is included in an infrared sensor.

The infrared sensor according to the embodiment will be described with reference to FIG. 3. FIG. 3 is a schematic cross-sectional view showing an example of the constitution of an infrared sensor comprising the cured film according to the embodiment of the present invention. An infrared sensor 300 shown in FIG. 3 comprises a solid-state imaging element 310.

An imaging region provided on the solid-state imaging element 310 is constituted with a combination of an infrared absorption filter 311 and a color filter 312 according to the embodiment of the present invention.

The infrared absorption filter 311 is a film which transmits light (for example, light having wavelengths of 400 to 700 nm) in the visible light range and shields light (for example, light having wavelengths of 800 to 1,300 nm, preferably light having wavelengths of 900 to 1,200 nm, and more preferably light having wavelengths of 900 to 1,000 nm) in the infrared range, and a cured film containing an infrared absorber (the aspect of the infrared absorber is as described above) as a colorant can be used.

The color filter 312 is a color filter in which pixels transmitting or absorbing light having a specific wavelength in the visible light range are formed, a color filter in which pixels of red (R), green (G), and blue (B) are formed, or the like is used as an example of the color filter, and the aspect thereof is as described above.

Between an infrared transmission filter 313 and the solid-state imaging element 310, a resin film 314 (for example, a transparent resin film or the like), which is capable of transmitting light having a wavelength transmitted through the infrared transmission filter 313, is disposed.

The infrared transmission filter 313 is a filter which has visible light-shielding properties and transmits infrared rays having a specific wavelength, and the cured film according to the embodiment of the present invention can be used which contains a colorant (for example, a perylene compound and/or a bisbenzofuranone compound) absorbing light in a visible light range, and an infrared absorber (for example, a pyrrolopyrrole compound, a phthalocyanine compound, a naphthalocyanine compound, a polymethine compound, and the like). It is preferable that the infrared transmission filter 313 shields light having wavelengths of 400 to 830 nm and transmits light having wavelengths of 900 to 1,300 nm, for example.

On an incidence ray hv side of the color filter 312 and the infrared transmission filter 313, microlenses 315 are arranged. A planarization film 316 is formed to cover the microlenses 315.

In the aspect shown in FIG. 3, the resin film 314 is disposed, but the infrared transmission filter 313 may be formed instead of the resin film 314. That is, on the solid-state imaging element 310, the infrared transmission filter 313 may be formed.

In the aspect shown in FIG. 3, the film thickness of the color filter 312 is the same as the film thickness of the infrared transmission filter 313, but both the film thicknesses may be different from each other.

In the aspect shown in FIG. 3, the color filter 312 is provided to be closer to the incidence ray hv side than the infrared absorption filter 311, but the order of the infrared absorption filter 311 and the color filter 312 may be switched so that the infrared absorption filter 311 is provided to be closer to the incidence ray hv side than the color filter 312.

In the aspect shown in FIG. 3, the infrared absorption filter 311 and the color filter 312 are laminated to be adjacent to each other, but both the filters are not necessarily adjacent to each other, and another layer may be provided between the filters. The cured film according to the embodiment of the present invention can be used as a light-shielding film on an edge of the surface and/or a lateral surface of the infrared absorption filter 311, and, by being used as a device inner wall of an infrared sensor, can prevent internal reflection and/or unintended incidence of light on the light receiving section and can improve sensitivity.

According to the infrared sensor, image information can be simultaneously taken in, and thus motion sensing or the like by which a subject whose movement is to be detected is recognized can be carried out. Moreover, since distance information can be obtained by the infrared sensor, images including 3D information and the like can also be captured. Furthermore, the infrared sensor can also be used as a biometric authentication sensor.

Next, a solid-state imaging device to which the aforementioned infrared sensor is applied will be described.

The solid-state imaging device includes a lens optical system, a solid-state imaging element, an infrared light-emitting diode, and the like. Furthermore, regarding each of the constituents of the solid-state imaging device, reference can be made to paragraphs 0032 to 0036 of JP2011-233983A, the contents of which are incorporated into the specification of the present application.

[Headlight Unit]

It is also preferable that the cured film according to the embodiment of the present invention is included, as the light-shielding film, in a headlight unit of a lighting tool for a vehicle such as an automobile. The cured film according to the embodiment of the present invention, which is included in the headlight unit as the light-shielding film, is preferably formed in a pattern shape so as to shield at least a part of light emitted from a light source.

The headlight unit according to the embodiment will be described with reference to FIGS. 4 and 5. FIG. 4 is a schematic view showing an example of the constitution of the headlight unit, and FIG. 5 is a schematic perspective view showing an example of the constitution of a light-shielding part of the headlight unit.

As shown in FIG. 4, a headlight unit 10 includes a light source 12, a light-shielding part 14, and a lens 16, and the light source 12, the light-shielding part 14, and the lens 16 are arranged in this order.

As shown in FIG. 5, the light-shielding part 14 has a substrate 20 and a light-shielding film 22.

In the light-shielding film 22, a pattern-like opening part 23 for radiating light emitted from the light source 12 into a specific shape is formed. A light distribution pattern radiated from the lens 16 is determined by the shape of the opening part 23 of the light-shielding film 22. The lens 16 projects light L from the light source 12, which has passed through the light-shielding part 14. In a case where a specific light distribution pattern can be radiated from the light source 12, the lens 16 is not necessarily required. The lens 16 is appropriately determined according to an irradiation distance and an irradiation range of the light L.

Moreover, a configuration of the substrate 20 is not particularly limited as long as the substrate can hold the light-shielding film 22, but the substrate 20 is preferably not deformed by the heat of the light source 12, and is made of glass, for example.

An example of the light distribution pattern is shown in FIG. 5, but the present invention is not limited to the example.

Furthermore, the number of the light sources 12 is also not limited to one, and the light sources may be arranged in a row or in a matrix, for example. In a case where a plurality of light sources are provided, for example, one light-shielding part 14 may be provided for one light source 12. In this case, the respective light-shielding film 22 of a plurality of light-shielding parts 14 may all have the same pattern or may have different patterns.

The light distribution pattern based on the pattern of the light-shielding film 22 will be described.

FIG. 6 is a schematic view showing an example of the light distribution pattern formed by the headlight unit, and FIG. 7 is a schematic view showing another example of the light distribution pattern formed by the headlight unit. Moreover, a light distribution pattern 30 shown in FIG. 6 and a light distribution pattern 32 shown in FIG. 7 both indicate a region irradiated with light. Further, a region 31 shown in FIG. 6 and a region 31 shown in FIG. 7 both indicate an irradiation region irradiated by the light source 12 (see FIG. 4) in a case where the light-shielding film 22 is not provided.

Due to the pattern of the light-shielding film 22, the intensity of light is sharply reduced at an edge 30a, for example, as in the light distribution pattern 30 shown in FIG. 6. The light distribution pattern 30 shown in FIG. 6 is, for example, a pattern in which light is not flashed at an oncoming vehicle in a case of left-side traveling.

Furthermore, as in the light distribution pattern 32 shown in FIG. 7, a pattern in which a part of the light distribution pattern 30 shown in FIG. 6 is cut out may be used. Also in this case, similar to the light distribution pattern 30 shown in FIG. 6, the intensity of light is sharply reduced at an edge 32a, and the pattern is, for example, a pattern in which light is not flashed at an oncoming vehicle in a case of left-side traveling. Moreover, the intensity of light is sharply reduced even at a cutout part 33. Therefore, in a region corresponding to the cutout part 33, a mark indicating a state such as a curved road, upward inclination, and downward inclination can be displayed. By doing so, safety during night-time traveling can be improved.

In addition, the light-shielding part 14 is not limited to being fixedly disposed between the light source 12 and the lens 16, and a configuration in which the light-shielding part 14 is allowed to enter between the light source 12 and the lens 16, if necessary, by a driving mechanism (not shown) to obtain a specific light distribution pattern may be adopted.

Moreover, in the light-shielding part 14, a shade member capable of shielding the light from the light source 12 may be formed. In this case, a configuration in which the shade member is allowed to enter between the light source 12 and the lens 16, if necessary, by the driving mechanism (not shown) to obtain a specific light distribution pattern may be adopted.

### EXAMPLES

Hereinafter, the present invention will be described in more detail based on Examples. The materials, the amounts of the materials used, the proportions, the treatment contents, the treatment procedure, and the like shown in the following Examples can be appropriately modified as long as the gist of the present invention is maintained. Accordingly, the scope of the present invention will not be restrictively interpreted by the following Examples.

[Preparation of Coloring Material Composition]

A coloring material composition containing the following black coloring material was prepared, and used in preparation of a light-shielding composition.

<Preparation of Dispersion Liquid of Titanium Black (Coloring Material A-1)>

100 g of titanium oxide MT-150A (trade name, produced by TAYCA) having an average particle diameter of 15 nm, 25 g of silica particles AEROSIL (registered trademark) 300/30 (produced by Evonik Industries AG) having a BET surface area of 300 m²/g, and 100 g of dispersant Disperbyk190 (trade name, produced by BYK-Chemie GmbH) were weighed and mixed. To the obtained mixture, 71 g of ion-electric exchange water was added. The obtained mixture was treated for 20 minutes at a revolution speed of 1,360 rpm and a rotation speed of 1,047 rpm using MAZERUSTAR KK-400W manufactured by KURABO INDUSTRIES LTD. to obtain a uniform dispersion liquid. A quartz vessel was filled with the dispersion liquid, and heated to 920° C. in an oxygen atmosphere using a small-sized rotary kiln (manufactured by Motoyama). Thereafter, the atmosphere was replaced with nitrogen, and a nitriding reduction treatment was performed by flowing an ammonia gas at 100 mL/min at the same temperature for 5 hours. After the completion of the nitriding reduction treatment, the collected powders were pulverized in a mortar to obtain powdery titanium black (coloring material A-1) having a specific surface area of 73 m²/g.

A dispersant X-1 (10 parts by mass) having the following structure was added to the coloring material A-1 (30 parts by mass) obtained above, and then propylene glycol monomethyl ether acetate (hereinafter, described as “PGMEA”) was further added so that the concentration of the solid content was 35% by mass.

[chemical structure]

In the structural formulae, the number attached to each repeating unit means a molar ratio of each repeating unit. Moreover, in the dispersant X-1, the acid value was 58 mg KOH/g and the weight-average molecular weight was 32,000.

The obtained dispersion was sufficiently stirred with a stirrer to perform premixing. The obtained dispersion was subjected to a dispersion treatment using a disperser NPM Pilot (trade name, manufactured by Shinmaru Enterprises Corporation) under the following conditions to obtain a dispersion liquid containing the coloring material A-1.

(Dispersion conditions)
Bead size: ϕ 0.05 mm
Bead filling rate: 65% by volume
Circumferential speed of mill: 10 m/sec
Circumferential speed of separator: 11 m/s
Amount of mixed solution subjected to dispersion treatment: 15.0 g
Circulation flow rate (pump supply rate): 60 kg/hour
Temperature of treatment liquid: 20° C. to 25° C.
Coolant: Tap water (5° C.)
Inner volume of annular passage of beads mill: 2.2 L
Number of passes: 84 passes

<Preparation of Dispersion Liquid of Resin-Coated Carbon Black (Coloring Material A-2)>

Carbon black was produced by an ordinary oil furnace method. Here, ethylene bottom oil having a small amount of Na, a small amount of Ca, and a small amount of S was used as stock oil, and combustion was performed using a gas fuel. Moreover, pure water treated with an ion exchange resin was used as reaction stop water.

The obtained carbon black (540 g) was stirred together with pure water (14,500 g) using a homomixer at 5,000 to 6,000 rpm for 30 minutes to obtain a slurry. The slurry was transferred to a container with a screw-type stirrer, and toluene (600 g) in which an epoxy resin “EPIKOTE 828” (produced by Japan Epoxy Resins Co., Ltd.) (60 g) was dissolved was added little by little into the container while performing mixing at about 1,000 rpm. In about 15 minutes, the total amount of the carbon black dispersed in water was transferred to the toluene side, thereby forming grains having a particle diameter of about 1 mm.

Next, draining was performed with a wire mesh having 60 meshes, and then the separated grains were placed in a vacuum dryer and dried at 70° C. for 7 hours to remove toluene and water, thereby obtaining resin-coated carbon black (coloring material A-2). The resin-coating amount of the obtained resin-coated carbon black was 10% by mass with respect to the total amount of the carbon black and the resin.

The dispersant X-1 (9 parts by mass) and SOLSPERSE 12000 (produced by Lubrizol Japan Limited) (1 part by mass) were added to the coloring material A-2 (30 parts by mass) obtained above, and then PGMEA was added so that the concentration of the solid content was 35% by mass. The dispersant X-1 is the same as that used in the preparation of the dispersion liquid of the coloring material A-1.

The obtained dispersion was sufficiently stirred with a stirrer to perform premixing. The obtained dispersion was subjected to a dispersion treatment using ULTRA APEX MILL UAM015 manufactured by HIROSHIMA METAL & MACHINERY CO., LTD. under the following conditions to obtain a dispersion composition. After the completion of the dispersion, the beads and the dispersion liquid were separated with a filter to obtain a dispersion liquid containing the coloring material A-2.

(Dispersion conditions)
Bead size: ϕ 0.05 mm
Bead filling rate: 75% by volume
Circumferential speed of mill: 8 m/sec
Amount of mixed solution subjected to dispersion treatment: 500 g
Circulation flow rate (pump supply rate): 13 kg/hour
Temperature of treatment liquid: 25° C. to 30° C.
Coolant: Tap water (5° C.)
Inner volume of annular passage of beads mill: 0.15 L
Number of passes: 90 passes

<Preparation of Dispersion Liquid of Organic Pigment (Coloring Material A-3)>

An organic pigment (Irgaphor Black S0100CF (produced by BASF SE)) (150 parts by mass) as a coloring material A-3, the dispersant X-1 (75 parts by mass), SOLSPERSE 20000 (pigment derivative, produced by Lubrizol Japan Limited) (25 parts by mass), and 3-methoxy butyl acetate (MBA) (750 parts by mass) were mixed. The dispersant X-1 is the same as that used in the preparation of the dispersion liquid of the coloring material A-1.

The obtained mixture was stirred for 20 minutes using a homomixer (manufactured by PRIMIX Corporation) to obtain a preliminary dispersion liquid. Moreover, the obtained preliminary dispersion liquid was subjected to a dispersion treatment for 3 hours using ULTRA APEX MILL (manufactured by HIROSHIMA METAL & MACHINERY CO., LTD.) equipped with a centrifugal separator under the following dispersion conditions to obtain a dispersion composition. After the completion of the dispersion, the beads and the dispersion liquid were separated with a filter to obtain a dispersion liquid containing the organic pigment (coloring material A-3). The concentration of the solid content of the obtained dispersion liquid was 25% by mass, and a ratio of coloring material A-3/resin component (the total of the dispersant X-1 and the pigment derivative) was 60/40 (mass ratio).

(Dispersion Conditions)
Used Beads: Zirconia beads having ϕ 0.30 mm (YTZ ball, manufactured by Neturen Co., Ltd)
Bead filling rate: 75% by volume
Circumferential speed of mill: 8 m/sec
Amount of mixed solution subjected to dispersion treatment: 1,000 g
Circulation flow rate (pump supply rate): 13 kg/hour
Temperature of treatment liquid: 25° C. to 30° C.
Coolant: Tap water (5° C.)
Inner volume of annular passage of beads mill: 0.15 L
Number of passes: 90 passes

<Preparation of Black Dye (Coloring Material A-4) Solution>

The dispersant X-1 (5.5 parts by mass) was added to VALIFAST BLACK 3804 (trade name, produced by Orient Chemical Industries Co., Ltd., dye specified by C. I. of SOLVENT BLACK 34) (20 parts by mass) as a coloring material A-4. Subsequently, the mixture was dissolved in PGMEA (74.5 parts by mass) to obtain a solution containing the coloring material A-4. The dispersant X-1 is the same as that used in the preparation of the dispersion liquid of the coloring material A-1.

[Alkali-Soluble Resin]

In order to prepare the light-shielding composition, a resin solution containing each of the following alkali-soluble resins B-1 to B-3 was used.
Alkali-soluble resin B-1: Resin (acid value: 31.5 mg KOH/g) having a structure represented by Formula (B-1)
Alkali-soluble resin B-2: KAYARAD ZCR-1569H (trade name, produced by Nippon Kayaku Co., Ltd.): Ethylenically unsaturated group-containing epoxy resin (acid value: 98 mg KOH/g)
Alkali-soluble resin B-3: Resin (acid value: 112.8 mg KOH/g) having a structure represented by Formula (B-3)

In the following structural formulae, the number attached to each repeating unit means a content (molar ratio) of each repeating unit in the resin.

[chemical structure]

[Polymerization Initiator]

The following polymerization initiators were used in the preparation of the light-shielding composition.
Polymerization initiator C-1: Compound represented by Formula (C-3)
Polymerization initiator C-2: IRGACURE OXE-02 (trade name, produced by BASF SE)
Polymerization initiator C-3: IRGACURE 369 (trade name, produced by BASF SE) The polymerization initiators are all photopolymerization initiators, and among the polymerization initiators, the polymerization initiators C-1 and C-2 are oxime ester-based polymerization initiators.

[chemical structure]

[Polymerizable Compound]

The following polymerizable compounds were used in the preparation of the composition.
Polymerizable compound D-1: NK ESTER A-TMMT (trade name, produced by Shin-Nakamura Chemical Co., Ltd.) (tetrafunctional acrylate)
Polymerizable compound D-2: KAYARAD DPHA (trade name, produced by Nippon Kayaku Co., Ltd.) (pentafunctional acrylate and hexafunctional acrylate)

The value of the “functional” indicates the number of ethylenically unsaturated groups contained in one molecule of the polymerizable compound.

Furthermore, the polymerizable compound D-2 is represented by the following structural formula. Moreover, the polymerizable compound D-2 is a mixture of a pentafunctional polymerizable compound and a hexafunctional polymerizable compound, and a mixing ratio thereof satisfies pentafunctional polymerizable compound/hexafunctional polymerizable compound=30/70 (mass ratio).

[chemical structure]

[Specific Particles]

The following specific particles E-1 to E-6 and CE-1 to CE-4 were used in the preparation of the light-shielding composition.
E-1: THRULYA 4110 (trade name, produced by JGC Catalysts and Chemicals Ltd.): Hollow silica particles, particle diameter of 60 nm
E-2: MX020W (trade name, produced by NIPPON SHOKUBAI CO., LTD.): Acrylic crosslinked resin particles, particle diameter of 20 nm
E-3: Viscoexcel-30 (trade name, produced by Shiraishi Calcium Kaisha Ltd.): Calcium carbonate particles, particle diameter of 30 nm
E-4: SI-45P (trade name, produced by JGC Catalysts and Chemicals Ltd.): Silica particles, particle diameter of 45 nm
E-5: Rosary-like silica, particle diameter of primary particle of 15 nm
E-6: TTO-51(C) (trade name, produced by ISHIHARA SANGYO KAISHA, LTD.): Titania particles, particle diameter of 20 nm
CE-1: SS-120 (trade name, produced by JGC Catalysts and Chemicals Ltd.): Silica particles, particle diameter of 120 nm
CE-2: SO-C1 (trade name, produced by Admatechs): Silica particles, particle diameter of 250 nm
CE-3: SO-C3 (trade name, produced by Admatechs): Silica particles, particle diameter of 900 nm
CE-4: SO-05 (trade name, produced by Admatechs): Silica particles, particle diameter of 1,600 nm

Among them, all of the specific particles except the specific particles E-1 do not have a hollow structure.

Furthermore, the specific particles E-5 (rosary-like silica) were prepared according to the method described in paragraphs 0032 to 0034 and 0042 (example 1-1) of JP2013-253145A.

In the following preparation of the light-shielding composition, a dispersion liquid containing 20% by mass of each of the aforementioned specific particles was used.

[Polymerization Inhibitor]

The following polymerization inhibitor was used in the preparation of the light-shielding composition.
p-Methoxyphenol

[Solvent]

The following solvents were used in the preparation of the light-shielding composition.
Cyclohexanone
PGMEA
Propylene glycol monomethyl ether
n-Butyl acetate

### Example 1

<Preparation of Light-Shielding Composition 1>

The following components were mixed with a stirrer to prepare a light-shielding composition 1 of Example 1.

| | | |
|---|---|---|
| Dispersion liquid of coloring material | 75 | parts by mass |
| A-1 prepared above | | |
| Alkali-soluble resin B-1 | 0.7 | parts by mass |
| Polymerization initiator C-1 | 1.1 | parts by mass |
| Polymerizable compound D-1 | 3 | parts by mass |
| Dispersion liquid of specific particles | 8.2 | parts by mass |
| E-1 (concentration of solid content of | | |
| 20% by mass) | | |
| Polymerization inhibitor | 0.003 | parts by mass |
| Cyclohexanone (solvent) | 10 | parts by mass |

<Production of Substrate with Light-Shielding Film>

The light-shielding composition 1 obtained above was applied onto a circular glass substrate having a diameter of 20 cm by a spin coating method to form a coating film having a thickness of 1.5 μm. The substrate with a coating film was pre-baked at 100° C. for 120 seconds, and then the entire surface of the substrate was exposed at an exposure amount of 500 mJ/cm² with a high-pressure mercury lamp (lamp power of 50 mW/cm²) using UX-1000SM-EH04 (manufactured by Ushio Inc.). The exposed substrate was post-baked at 220° C. for 300 seconds to obtain a substrate with a light-shielding film.

Table 1 shows the composition of the light-shielding composition obtained in Example 1, and the content (% by mass) of each of the coloring material A-1 and the specific particles E-1 with respect to the total solid content of the light-shielding composition.

<Production of Substrate with Pattern-Like Light-Shielding Film>

The light-shielding composition 1 obtained above was applied onto a circular glass substrate having a diameter of 20 cm by a spin coating method to form a coating film having a thickness of 1.5 μm. The substrate with a coating film was pre-baked at 100° C. for 120 seconds. Subsequently, the substrate with a coating film was subjected to exposure in a proximity manner through a mask with a line and space (L/S) pattern having an opening line width of 50 μm at an exposure amount of 500 mJ/cm² with a high-pressure mercury lamp (lamp power of 50 mW/cm²) using UX-1000SM-EH04 (trade name, manufactured by Ushio Inc.). Next, the substrate was subjected to puddle development with a developer “CD-1040” (trade name, produced by FUJIFILM Electronic Materials Co., Ltd.) for 15 seconds using AD-1200 (manufactured by MIKASA CO., LTD.), and then washed with pure water for 30 seconds using a shower nozzle to remove an uncured part. The obtained substrate with a coating film was post-baked at 220° C. for 300 seconds to obtain a substrate with a pattern-like light-shielding film of Example 1.

### Examples 2 to 20 and Comparative Examples 1 to 10

<Preparation of Light-Shielding Compositions 2 to 20 and Comparative Light-Shielding Compositions C1 to C10>

Light-shielding compositions 2 to 20 and comparative light-shielding compositions C1 to C10 were respectively prepared in the same manner as in Example 1, except that the respective components used were changed and the addition amounts of each coloring material composition and each dispersion liquid of the specific particles were adjusted so that the composition of the light-shielding composition satisfied each of the compositions shown in Tables 1 to 3.

Furthermore, the description of “D-1/D-2=1/1” in a column of “Polymerizable compound” of Example 20 and Comparative Example 10 indicates that the polymerizable compound D-1 and the polymerizable compound D-2 were added so that the mass ratio of the both polymerizable compounds was 1:1 and the total addition amount of the both polymerizable compounds was the same as the addition amount of the polymerizable compound D-1 in Example 1.

<Production of Substrates with Light-Shielding Film and Substrates with Pattern-Like Light-Shielding Film>

Substrates with a light-shielding film and substrates with a pattern-like light-shielding film of Examples 2 to 20 and Comparative Examples 1 to 10 were respectively produced in the same manner as in Example 1, except that the light-shielding compositions 2 to 20 and C1 to C10 obtained above were used.

### EVALUATION

The respective substrates with a light-shielding film obtained above were used for the following tests and evaluations.

[Evaluation of Low-Reflection Properties]

In each of the substrates with a light-shielding film obtained above, 10 spots arranged at intervals of 1 cm in a radial direction from the center of the substrate were set. Light having wavelengths of 350 to 1,200 nm was incident toward the respective spots on the substrate at an incidence angle of 5° using a VAR unit of a spectrometer V7200 (trade name, manufactured by JASCO Corporation). From reflectivities at wavelengths 550 nm and 940 nm obtained from reflected light spectra obtained at the respective spots, an average value of reflectivities at the respective wavelengths was calculated. The low-reflection properties of each light-shielding film were evaluated according to the following viewpoints, based on the obtained reflectivity (average reflectivity) at each wavelength.

A: The reflectivity was less than 1%

B: The reflectivity was equal to or greater than 1% and less than 3%

C: The reflectivity was equal to or greater than 3% and less than 5%

D: The reflectivity was equal to or greater than 5%

[Evaluation of in-Plane Uniformity of Reflectivity]

In each of the substrates with a light-shielding film, differences between the reflectivities at a wavelength of 550 nm at the respective spots and the calculated average value of the reflectivities at a wavelength of 550 nm, which were obtained in the reflectivity measurement test, were respectively calculated. The in-plane uniformity (hereinafter, simply described as “in-plane uniformity” as well) of the reflectivity of each substrate with a light-shielding film was evaluated according to the following viewpoints, based on the maximum value among absolute values of the calculated differences for the respective spots.

A: The maximum value of the difference was less than 0.5%

B: The maximum value of the difference was equal to or greater than 0.5% and less than 1%

C: The maximum value of the difference was equal to or greater than 1% and less than 1.5%

D: The maximum value of the difference was equal to or greater than 1.5%

[Evaluation of Light-Shielding Properties (Optical Density)]

The optical density (OD) of each of the substrates with a light-shielding film obtained above was measured using an integrating sphere-type light-receiving unit of a spectrophotometer U-4100 (trade name, manufactured by Hitachi High-Technologies Corporation). The measured optical density was an optical density per film thickness of the light-shielding film of 1.5 μm in a wavelength range of 400 to 1,200 nm. The optical density of the light-shielding film is preferably equal to or higher than 3 and more preferably equal to or higher than 3.2. In a case where the optical density of the light-shielding film is lower than 2.5, there is a possibility of being problematic for practical use as a light-shielding film.

[Evaluation of Light Resistance]

Each of the substrates with a light-shielding film obtained above was subjected to an irradiation test for 500 hours under conditions of a lamp illuminance of 75 W/m² (300 to 400 nm) and a humidity of 50% RH using a light resistance tester (Super Xenon Weather Meter (trade name) manufactured by Suga Test Instruments Co., Ltd.). The film thicknesses of the light-shielding film before and after the irradiation test were measured using a contact-type film thickness meter. The light resistance of each light-shielding film was evaluated according to the following viewpoints, based on the amount of change in the film thickness of the light-shielding film before and after the irradiation test.

A: The ratio of the amount of change in the film thickness before and after the irradiation test to the film thickness before the irradiation test was less than 2%

B: The ratio of the amount of change in the film thickness before and after the irradiation test to the film thickness before the irradiation test was equal to or greater than 2% and less than 5%

C: The ratio of the amount of change in the film thickness before and after the irradiation test to the film thickness before the irradiation test was equal to or greater than 5%

[Evaluation of Moisture Resistance]

Each of the substrates with a pattern-like light-shielding film obtained above was placed in a constant temperature and humidity tank, and subjected to a moisture resistance test for 500 hours under conditions of 85° C. and 85% RH. In the substrate after the moisture resistance test, a cross section of a line pattern having an opening line width of 50 μm was observed using a scanning electron microscope (SEM)S-4800 (trade name, manufactured by JEOL Ltd.). The presence or absence of pattern peeling was evaluated according to the following viewpoints, based on the SEM image of the obtained cross section.

A: No peeling is observed in the entire pattern.

B: Peeling is observed in some parts of the pattern.

C: Most of the pattern is peeled off.

[Result]

Tables 1 to 3 show the compositions of the light-shielding compositions prepared in Examples 1 to 20 and Comparative Examples 1 to 10, and the results of each test for the light-shielding films produced using the light-shielding compositions.

In Tables 1 to 3, a column of “Content” indicates the ratio (% by mass) of the content of each coloring material or each specific particle to the total solid content of each light-shielding composition.

In Tables 1 to 3, a column of “Particle diameter” indicates the particle diameter (nm) of each specific particle.

In Tables 1 to 3, a column of “Specific ratio” indicates the ratio (mass ratio) of the content of each specific particle to the content of each coloring material in each light-shielding composition.

TABLE 1

| | | | | Example 1 | Example 2 | Example 3 | Example 4 | Example 5 | Example 6 |
|---|---|---|---|---|---|---|---|---|---|
| Light- | No. | | | 1 | 2 | 3 | 4 | 5 | 6 |
| shielding | Composition | Coloring | Type | A-1 | A-1 | A-1 | A-1 | A-1 | A-1 |
| composition | | material | Content | 60 | 60 | 60 | 60 | 60 | 60 |

| Dispersant | | X-1 | X-1 | X-1 | X-1 | X-1 | X-1 |
|---|---|---|---|---|---|---|---|
| Alkali-soluble resin | | B-1 | B-1 | B-1 | B-1 | B-1 | B-1 |
| Polymerization | | C-1 | C-1 | C-1 | C-1 | C-1 | C-1 |
| initiator | | | | | | | |
| Polymerization | | D-1 | D-1 | D-1 | D-1 | D-1 | D-1 |
| compound | | | | | | | |
| Specific | Type | E-1 | E-1 | E-1 | E-1 | E-1 | E-1 |
| particle | Particle | 60 | 60 | 60 | 60 | 60 | 60 |
| | diameter | | | | | | |
| | Content | 5 | 2.5 | 7.5 | 10 | 1 | 15 |

| | Specific ratio | 0.08 | 0.04 | 0.125 | 0.16 | 0.01 | 0.25 |
|---|---|---|---|---|---|---|---|
| Evaluation | Reflectivity at 550 nm | A | A | A | A | B | A |
| of light- | Reflectivity at 940 nm | A | A | A | A | B | A |
| shielding | In-plane uniformity | A | A | A | A | B | B |
| film | Optical density | 3.2 | 3.2 | 3.0 | 2.7 | 3.2 | 2.5 |
| | Light resistance | A | A | A | A | B | A |
| | Moisture resistance | A | A | A | B | A | B |

| | | | | Example 7 | Example 8 | Example 9 | Example 10 |
|---|---|---|---|---|---|---|---|
| Light- | No. | | | 7 | 8 | 9 | 10 |
| shielding | Composition | Coloring | Type | A-1 | A-1 | A-1 | A-1 |
| composition | | material | Content | 50 | 60 | 60 | 60 |

| Dispersant | | X-1 | X-1 | X-1 | X-1 |
|---|---|---|---|---|---|
| Alkali-soluble resin | | B-1 | B-1 | B-1 | B-1 |
| Polymerization | | C-1 | C-1 | C-1 | C-1 |
| initiator | | | | | |
| Polymerization | | D-1 | D-1 | D-1 | D-1 |
| compound | | | | | |
| Specific | Type | E-1 | E-2 | E-3 | E-4 |
| particle | Particle | 60 | 20 | 30 | 45 |
| | diameter | | | | |
| | Content | 5 | 5 | 5 | 5 |

| | Specific ratio | 0.1 | 0.08 | 0.08 | 0.08 |
|---|---|---|---|---|---|
| Evaluation | Reflectivity at 550 nm | A | A | B | B |
| of light- | Reflectivity at 940 nm | A | A | B | B |
| shielding | In-plane uniformity | A | A | B | A |
| film | Optical density | 2.5 | 3.2 | 3.2 | 3.2 |

| | | | | |
|---|---|---|---|---|
| Light resistance | A | B | B | A |
| Moisture resistance | A | B | B | A |

TABLE 2

| | | | | Example 11 | Example 12 | Example 13 | Example 14 | Example 15 | Example 16 |
|---|---|---|---|---|---|---|---|---|---|
| Light- | No. | | | 11 | 12 | 13 | 14 | 15 | 16 |
| shielding | Composition | Coloring | Type | A-4 | A-3 | A-2 | A-1 | A-1 | A-1 |
| composition | | material | Content | 60 | 60 | 60 | 60 | 60 | 60 |

| Dispersant | | X-1 | X-1 | X-1 | X-1 | X-1 | X-1 |
|---|---|---|---|---|---|---|---|
| Alkali-soluble resin | | B-1 | B-1 | B-1 | B-1 | B-1 | B-3 |
| Polymerization | | C-1 | C-1 | C-1 | C-2 | C-3 | C-1 |
| initiator | | | | | | | |
| Polymerization | | D-1 | D-1 | D-1 | D-1 | D-1 | D-1 |
| compound | | | | | | | |
| Specific | Type | E-1 | E-1 | E-1 | E-1 | E-1 | E-1 |
| particle | Particle | 60 | 60 | 60 | 60 | 60 | 60 |
| | diameter | | | | | | |
| | Content | 5 | 5 | 5 | 5 | 5 | 5 |

| | Specific ratio | 0.08 | 0.08 | 0.08 | 0.08 | 0.08 | 0.08 |
|---|---|---|---|---|---|---|---|
| Evaluation | Reflectivity at 550 nm | B | B | A | A | A | A |
| of light- | Reflectivity at 940 nm | B | B | A | A | A | A |
| shielding | In-plane uniformity | A | A | A | A | A | A |
| film | Optical density | 2.5 | 2.6 | 3.4 | 3.0 | 2.8 | 3.2 |
| | Light resistance | B | A | A | A | A | A |
| | Moisture resistance | B | B | B | B | C | B |

| | | | | Example 17 | Example 18 | Example 19 | Example 20 |
|---|---|---|---|---|---|---|---|
| Light- | No. | | | 17 | 18 | 19 | 20 |
| shielding | Composition | Coloring | Type | A-1 | A-1 | A-1 | A-1 |
| composition | | material | Content | 60 | 60 | 60 | 60 |

| Dispersant | | X-1 | X-1 | X-1 | X-1 |
|---|---|---|---|---|---|
| Alkali-soluble resin | | B-1 | B-1 | B-1 | B-1 |
| Polymerization | | C-1 | C-1 | C-1 | C-1 |
| initiator | | | | | |
| Polymerization | | D-2 | D-1 | D-1 | D-1/D-2 = |
| compound | | | | | 1/1 |
| Specific | Type | E-1 | E-5 | E-6 | E-1 |
| particle | Particle | 60 | 15 | 20 | 60 |
| | diameter | | | | |
| | Content | 5 | 5 | 5 | 5 |

| | Specific ratio | 0.08 | 0.08 | 0.08 | 0.08 |
|---|---|---|---|---|---|
| Evaluation | Reflectivity at 550 nm | A | B | A | A |
| of light- | Reflectivity at 940 nm | A | B | A | A |
| shielding | In-plane uniformity | A | B | A | A |
| film | Optical density | 3.1 | 2.8 | 3.1 | 3.2 |

| | | | | |
|---|---|---|---|---|
| Light resistance | A | B | A | A |
| Moisture resistance | A | A | A | A |

TABLE 3

| | | | | Comparative | Comparative | Comparative | Comparative | Comparative | Comparative |
|---|---|---|---|---|---|---|---|---|---|
| | | | | Example 1 | Example 2 | Example 3 | Example 4 | Example 5 | Example 6 |
| Light- | No. | | | C1 | C2 | C3 | C4 | C5 | C6 |
| shielding | Composition | Coloring | Type | A-1 | A-1 | A-1 | A-1 | A-1 | A-1 |
| composition | | material | Content | 60 | 60 | 60 | 60 | 60 | 60 |

| Dispersant | | X-1 | X-1 | X-1 | X-1 | X-1 | X-1 |
|---|---|---|---|---|---|---|---|
| Alkali-soluble resin | | B-1 | B-1 | B-1 | B-1 | B-1 | B-1 |
| Polymerization | | C-1 | C-1 | C-1 | C-1 | C-1 | C-1 |
| initiator | | | | | | | |
| Polymerization | | D-1 | D-1 | D-1 | D-1 | D-1 | D-1 |
| compound | | | | | | | |
| Specific | Type | — | CE-1 | CE-2 | CE-3 | CE-4 | E-1 |
| particle | Particle | — | 120 | 250 | 900 | 1600 | 60 |
| | diameter | | | | | | |
| | Content | 0 | 5 | 5 | 5 | 5 | 0.5 |

| | Specific ratio | 0 | 0.08 | 0.08 | 0.08 | 0.08 | 0.008 |
|---|---|---|---|---|---|---|---|
| Evaluation | Reflectivity at 550 nm | D | B | B | C | C | D |
| of light- | Reflectivity at 940 nm | D | B | B | B | C | D |
| shielding | In-plane uniformity | A | B | C | D | D | D |
| film | Optical density | 3.2 | 2.2 | 2.0 | 1.8 | 1.5 | 3.2 |
| | Light resistance | C | B | C | C | C | A |
| | Moisture resistance | A | C | C | C | c | C |

| | | | | Comparative | Comparative | Comparative | Comparative |
|---|---|---|---|---|---|---|---|
| | | | | Example 7 | Example 8 | Example 9 | Example 10 |
| Light- | No. | | | C7 | C8 | C9 | C10 |
| shielding | Composition | Coloring | Type | A-1 | A-1 | A-2 | A-1 |
| composition | | material | Content | 60 | 60 | 27.8 | 55 |

| Dispersant | | X-1 | X-1 | X-1 | X-1 |
|---|---|---|---|---|---|
| Alkali-soluble resin | | B-1 | B-1 | B-2 | B-3 |
| Polymerization | | C-1 | C-1 | C-2 | C-2 |
| initiator | | | | | |
| Polymerization | | D-1 | D-1 | D-2 | D-1/D-2 = |
| compound | | | | | 1/1 |
| Specific | Type | E-1 | E-1 | E-1 | CE-2 |
| particle | Particle | 60 | 60 | 60 | 250 |
| | diameter | | | | |
| | Content | 18 | 30 | 14 | 5 |

| | Specific ratio | 0.3 | 0.5 | 0.5 | 0.08 |
|---|---|---|---|---|---|
| Evaluation | Reflectivity at 550 nm | A | A | C | C |
| of light- | Reflectivity at 940 nm | A | A | C | C |
| shielding | In-plane uniformity | D | D | D | C |
| film | Optical density | 2.2 | 1.9 | 1.7 | 2.8 |

| | | | | |
|---|---|---|---|---|
| Light resistance | A | A | C | C |
| Moisture resistance | C | C | C | C |

From the results shown in Tables 1 to 3, it was confirmed that the objects of the present invention can be achieved by the light-shielding composition according to the embodiment of the present invention.

It was confirmed that the specific ratio is preferably greater than 0.01 from the viewpoint that the low-reflection properties, the in-plane uniformity, and the light-shielding properties of the light-shielding film are superior (comparison of Example 2 and Example 5).

Moreover, it was confirmed that the specific ratio is preferably less than 0.25 from the viewpoint that the in-plane uniformity of the light-shielding film is superior (comparison of Example 4 and Example 6).

Further, it was confirmed that the specific ratio is more preferably equal to or less than 0.15 from the viewpoint that the light-shielding properties and the moisture resistance of the light-shielding film are superior (comparison of Example 3 and Examples 4 and 6).

Furthermore, it was confirmed that the specific ratio is more preferably equal to or less than 0.09 from the viewpoint that the light-shielding properties of the light-shielding film are superior (comparison of Example 1 and Example 3).

It was confirmed that the content of the black coloring material is preferably greater than 50% by mass with respect to the total solid content of the light-shielding composition from the viewpoint that the light-shielding properties of the light-shielding film are superior (comparison of Example 1 and Example 7).

It was confirmed that the specific particles are preferably particles of an inorganic oxide or an acrylic resin from the viewpoint that the in-plane uniformity of the light-shielding film is superior (comparison of Examples 1, 8, 10, and 19 and Example 9).

Moreover, it was confirmed that the specific particles are preferably particles of an inorganic oxide from the viewpoint that the light resistance and the moisture resistance of the light-shielding film are superior (comparison of Examples 1, 10, and 19 and Examples 8 and 9).

Furthermore, it was confirmed that the specific particles are preferably particles having a hollow structure from the viewpoint that the low-reflection properties of the light-shielding film are superior (comparison of Example 1 and Example 10).

It was confirmed that the black coloring material is preferably a black pigment from the viewpoint that the light resistance of the light-shielding film is superior (comparison of Examples 1, 12, and 13 and Example 11).

Moreover, it was confirmed that the black coloring material is preferably an inorganic pigment from the viewpoint that the low-reflection properties and the light-shielding properties of the light-shielding film are superior (comparison of Examples 1 and 13 and Examples 11 and 12).

Furthermore, it was confirmed that the black coloring material preferably contains a titanium oxynitride from the viewpoint that the moisture resistance of the light-shielding film is superior (comparison of Example 1 and Examples 11 to 13).

It was confirmed that the polymerization initiator is preferably an oxime compound from the viewpoint that the moisture resistance and the light-shielding properties are superior (comparison of Examples 1 and 14 and Example 15).

Moreover, it was confirmed that the polymerization initiator is preferably a compound represented by Formula (C-3) from the viewpoint that the moisture resistance is superior (comparison of Example 1 and Examples 14 and 15).

It was confirmed that the alkali-soluble resin preferably contains an ethylenically unsaturated group from the viewpoint that the moisture resistance is superior (comparison of Example 1 and Example 16).

### Example 21

A light-shielding composition 21 was prepared according to the method for preparing the light-shielding composition 1 of Example 1, except that the polymerization inhibitor was not used. A substrate with a light-shielding film and a substrate with a pattern-like light-shielding film were produced according to the method described in Example 1, except that the obtained light-shielding composition 21 was used instead of the light-shielding composition 1, and each light-shielding film was evaluated. The evaluation results of the light-shielding film of Example 21 were equivalent to those in Example 1.

### Examples 22 to 24

A dispersion liquid containing each coloring material was prepared according to the method for preparing the dispersion liquid of the coloring material A-1, except that each of the following coloring materials A-5 to A-7 was used instead of the titanium black (coloring material A-1).
Coloring material A-5: Vanadium nitride (trade name “VN-O”, produced by JAPAN NEW METALS CO., LTD.)
Coloring material A-6: Niobium nitride (trade name “NbN-O”, produced by JAPAN NEW METALS CO., LTD.)
Coloring material A-7: Zirconium nitride (which was prepared by the method of Example 1 of JP2017-222559A)

Light-shielding compositions 22 to 24 were respectively prepared according to the method for preparing the light-shielding composition 1 of Example 1, except that the dispersion liquid of each coloring material prepared above was used instead of the dispersion liquid of the coloring material A-1 and the polymerization inhibitor was not used. Substrates with a light-shielding film and substrates with a pattern-like light-shielding film were produced according to the method described in Example 1, except that the obtained light-shielding compositions 22 to 24 were respectively used instead of the light-shielding composition 1, and each light-shielding film was evaluated. The evaluation results of the light-shielding films of Examples 22 to 24 were all equivalent to those in Example 1.

In a case where a coloring material A-8 was used instead of the titanium black (coloring material A-1) and the evaluation was performed in the same manner as in Example 1, the results were equivalent to those in Example 1.
Coloring material A-8: Silica-coated zirconium nitride (JP2015-117302A)

Even in a case where the titanium black (coloring material A-1) was replaced with each mixture satisfying A-1:A-7=1:9, 3:7, 5:5, 7:3, or 9:1, the same effects could be obtained (the ratios were weight ratios). Moreover, even in a case where the titanium black was replaced with each mixture satisfying A-1:A-8=1:9, 3:7, 5:5, 7:3, or 9:1, the same effects could be obtained (the ratios were weight ratios).

### Example 25

A light-shielding composition 25 of Example 25 was prepared according to the method of Example 1, except that the total amount of coloring materials was the same as that of the light-shielding composition 1, and the amounts of the dispersion liquid of the coloring material A-1 and the dispersion liquid of the coloring material A-3 were adjusted so that the mass ratio of the coloring material A-1 and the coloring material A-3 was 1:1, in the preparation of the light-shielding composition 1. A substrate with a light-shielding film and a substrate with a pattern-like light-shielding film were produced according to the method described in Example 1, except that the obtained light-shielding composition 25 was used instead of the light-shielding composition 1, and each light-shielding film was evaluated. In the evaluation of the light-shielding film of Example 25, the results were equivalent to those in Example 1, except that the optical density was 3.0 and the moisture resistance was B.

### Examples 26 to 28

Light-shielding compositions 26 to 28 were respectively prepared according to the method for preparing the light-shielding composition 1 of Example 1, except that PGMEA, propylene glycol monomethyl ether, or n-butyl acetate was used instead of the cyclohexanone as the solvent. Substrates with a light-shielding film and substrates with a pattern-like light-shielding film were produced according to the method described in Example 1, except that the obtained light-shielding compositions 26 to 28 were respectively used instead of the light-shielding composition 1, and each light-shielding film was evaluated. The evaluation results of the light-shielding films of Examples 26 to 28 were all equivalent to those in Example 1.

### Example 29

<Production of Color Filter Comprising Black Matrix>

The light-shielding composition 1 of Example 1 was applied to a glass wafer by a spin coating method to form a composition layer. Next, the glass wafer was placed on a hot plate, and pre-baked at 120° C. for 2 minutes. Then, the composition layer was exposed through a photo mask having an island pattern of 0.1 mm at an exposure amount of 500 mJ/cm² using an i-line stepper.

Subsequently, the exposed composition layer was subjected to puddle development at 23° C. for 60 seconds using an aqueous solution of 0.3% tetramethylammonium hydroxide to obtain a cured film. Then, the cured film was rinsed using a spin shower, and further washed with pure water. By doing so, a pattern-like light-shielding film (black matrix) was obtained. In a case where a color filter was produced using the aforementioned black matrix, the color filter had favorable performances.

### Example 30

<Production of Solid-State Imaging Element Comprising Cured Film>

A curable composition for a lens (composition obtained by adding 1% by mass of an arylsulfonium salt derivative (produced by ADEKA CORPORATION, trade name “SP-172”) to an alicyclic epoxy resin (produced by Daicel Corporation, trade name “EHPE-3150”)) (2 mL) was applied onto a glass substrate (thickness of 1 mm, manufactured by SCHOTT AG, trade name “BK7”) of 5×5 cm, and the coating film was cured by heating at 200° C. for 1 minute to form a lens film in which residues on the lens could be evaluated.

The light-shielding composition 1 of Example 1 was applied onto the glass wafer, on which the lens film was formed, to form a composition layer. Then, the glass wafer was placed on a hot plate, and pre-baked at 120° C. for 120 seconds. The thickness of the composition layer after the heating was 2.0 μm.

Next, the composition layer was exposed through a photo mask having a hole pattern of 10 mm at an exposure amount of 500 mJ/cm² using a high-pressure mercury lamp. Subsequently, the exposed composition layer was subjected to puddle development at a temperature of 23° C. for 60 seconds using an aqueous solution of 0.3% tetramethylammonium hydroxide to obtain a pattern-like cured film (light-shielding film). The obtained pattern-like cured film was rinsed using a spin shower, and further washed with pure water.

On the glass wafer on which the cured film produced above was formed, a curable resin layer was formed using a curable composition for a lens (composition obtained by adding 1% by mass of an arylsulfonium salt derivative (produced by ADEKA CORPORATION, trade name “SP-172”) to an alicyclic epoxy resin (produced by Daicel Corporation, trade name “EHPE-3150”)). Subsequently, a shape was transferred with a quartz mold having a lens shape, and the curable resin layer was cured by performing exposure at an exposure amount of 400 mJ/cm² with a high-pressure mercury lamp, thereby producing a wafer-level lens array having a plurality of wafer-level lenses.

The produced wafer-level lens array was cut, a lens module was produced using the obtained wafer-level lens, and then an imaging element and a sensor substrate were attached thereto to produce a solid-state imaging element comprising the cured film according to the embodiment of the present invention.

In the obtained solid-state imaging element, residues were not present in a lens opening part of the wafer-level lens and thus favorable transmission properties were exhibited, and the light-shielding film had high uniformity of the coated surface and high light-shielding properties.

### Example 31

<Production of Headlight Unit Comprising Cured Film>

The light-shielding composition 1 of Example 1 obtained above was applied onto a glass substrate of 10 cm square by a spin coating method to form a composition layer. The glass substrate was placed on a hot plate, and pre-baked at 120° C. for 2 minutes.

The obtained composition layer was exposed (exposure amount of 1,000 mJ/cm²) through a mask using an i-line stepper so that a light-shielding film having the light distribution pattern shown in FIG. 6 could be obtained. Subsequently, a development treatment was performed using a development device (Act-8 manufactured by Tokyo Electron Limited). Puddle development was performed at 23° C. for 60 seconds using an aqueous solution of 0.3% tetramethylammonium hydroxide as a developer. Thereafter, rinse was performed with a spin shower using pure water to obtain a cured film having a predetermined light distribution pattern.

In a case where a headlight unit was produced using the obtained cured film, a light source, and a lens, the headlight unit had favorable performances.

### Explanation of References

10: Headlight unit
12: Light source
14: Light-shielding part
16: Lens
20: Substrate
22: Light-shielding film
23: Opening part
30: Light distribution pattern
30a: Edge
31: Region
32: Light distribution pattern
32a: Edge
33: Cutout part
100: Solid-state imaging device
101: Solid-state imaging element
102: Imaging part
103: Cover glass
104: Spacer
105: Laminated substrate
106: Chip substrate
107: Circuit substrate
108: Electrode pad
109: External connection terminal
110: Through electrode
111: Lens layer
112: Lens material
113: Support
114, 115: Light-shielding film
201: Light-receiving element
202: Color filter
203: Microlens
204: Substrate
205b: Blue pixel
205r: Red pixel
205g: Green pixel
205bm: Black matrix
206: p-well layer
207: Reading gate part
208: Vertical electric charge transfer path
209: Element separation region
210: Gate insulating film
211: Vertical electric charge transfer electrode
212: Light-shielding film
213, 214: Insulating film
215: Planarization film
300: Infrared sensor
310: Solid-state imaging element
311: Infrared absorption filter
312: Color filter
313: Infrared transmission filter
314: Resin film
315: Microlens
316: Planarization film

What is claimed is:

1. A light-shielding composition comprising:
a black coloring material;
a resin;
a polymerizable compound;
a polymerization initiator; and
particles,
wherein a particle diameter of each of the particles is equal to or greater than 1 nm and less than 100 nm, and
a mass ratio of a content of the particles to a content of the black coloring material is 0.01 to 0.25.

2. The light-shielding composition according to claim 1,
wherein the content of the black coloring material is greater than 50% by mass and equal to or less than 90% by mass with respect to a total solid content of the light-shielding composition.

3. The light-shielding composition according to claim 1,
wherein the particles contain an inorganic oxide, an inorganic nitride, a carbonate, or a resin.

4. The light-shielding composition according to claim 1,
wherein the particles contain an inorganic oxide.

5. The light-shielding composition according to claim 1,
wherein the particles contain at least one selected from the group consisting of silica, titania, and alumina.

6. The light-shielding composition according to claim 1,
wherein the particles are particles having a hollow structure.

7. The light-shielding composition according to claim 1,
wherein the content of the particles is greater than 1% by mass and less than 10% by mass with respect to a total solid content of the light-shielding composition.

8. The light-shielding composition according to claim 1,
wherein the black coloring material is an inorganic pigment.

9. The light-shielding composition according to claim 1,
wherein the black coloring material contains an oxynitride of at least one metal selected from the group consisting of titanium, vanadium, zirconium, and niobium.

10. The light-shielding composition according to claim 1,
wherein the polymerization initiator is an oxime compound.

11. The light-shielding composition according to claim 1,
wherein the content of the black coloring material is greater than 50% by mass and equal to or less than 90% by mass with respect to a total solid content of the light-shielding composition, and
the polymerization initiator is a fluorine atom-containing oxime compound.

12. The light-shielding composition according to claim 1,
wherein the polymerization initiator is a compound represented by Formula (C-3),

[chemical structure]

13. A cured film formed of the light-shielding composition according to claim 1.

14. A color filter comprising:
the cured film according to claim 13.

15. A light-shielding film comprising:
the cured film according to claim 13.

16. An optical element comprising:
the cured film according to claim 13.

17. A solid-state imaging element comprising:
the cured film according to claim 13.

18. A headlight unit for a vehicle lighting tool, the headlight unit comprising:
a light source; and
a light-shielding part which shields at least a part of light emitted from the light source,
wherein the light-shielding part includes the cured film according to claim 13.
